(19) United States
(12) Patent Application Publication
(10) Pub. No.: US 2023/0073096 A1
(43) Pub. Date: Mar. 9, 2023

(54) An Optical Effect Device

(71) Applicant: CCL Secure Pty Ltd, Craigieburn, Victoria (AU)

(72) Inventor: Karlo Ivan JOLIC, Craigieburn, Victoria (AU)

(21) Appl. No.: 17/760,285

(22) PCT Filed: Feb. 12, 2021
(86) PCT No.: PCT/AU2021/050122

§ 371 Date: Aug. 5, 2022

(30) Foreign Application Priority Data
Feb. 12, 2020 (AU) 2020900385

(51) Int. Cl. B42D 25/29; G03F 7/20; G02B 5/18

(52) U.S. Cl. CPC B42D 25/29; G03F 7/702; G02B 5/1857

(57) ABSTRACT

An optical effect device (300) comprising: a substrate (302) having a first surface (304) and a second surface (306); a plurality of structures (308) arranged on the first surface (304), each structure (308) having a first facet (310) and a second facet (314), the first facet (310) of each structure (308) being substantially parallel to the first surface (304) of the substrate (302), the second facet (314) of each structure (308) defining a slope with respect to the first surface (304), and the first facets (310) of the plurality of structures (308) forming a first facet set. The first facet set defines a first optical effect when the optical effect device (300) is viewed from a first viewing angle range

### FIELD OF THE INVENTION

The invention relates generally to the field of optical effect devices, in particular, to optical security devices, for example as used on banknotes.

### BACKGROUND TO THE INVENTION

It is well known that many of the world's banknotes, as well as other security documents, carry optical devices, which act as security elements for authentication purposes. Some optical security elements produce optical effects that vary depending on the viewing angle range or require a predetermined optical illumination source in order to reveal the optical effects. The incorporation of such optical security elements into security documents therefore acts as a deterrent against counterfeiting of the document.

Some optical security devices, for example lens based images, interlaced images, stereograms, integral images, magnifying moirés and the like suffer from a number of similar problems. For example, the limited resolution of pixels, the addressability of the pixels and the registration of different colours relative to one another. The physical size of lenses used in security device application is usually determined by a number of factors including sag height of the lens and focal length of the lens (intimately related to the thickness of the material upon which the lens will be formed and the distance to the focusing surface, usually the obverse side to the lens).

The issues of high-resolution images and colour registration (especially multicolour images) have been approached in the past by various different methods.

One method involves using diffractive imagery elements, where colours are created by diffraction elements located within a single surface. With this method, different colours are produced by changing the spacing between parallel diffractive grating elements to preferentially diffract one wavelength of light at a given angle of viewing.

Another method involves plasmonic structures whereupon conductive surfaces with sub wavelength periodic structures are created so that standing (resonant) waves of a particular frequency are created between the structures.

Another method involves using laser to alter structures of interference layers in a vacuum-deposited multilayer structure.

Another method involves creating structural colour by blending chiral and nematic liquid crystals. Whist the use of these two materials has long been known to create colour pairs at a given angle, the colour created is achieved by controlling the ratio of the pair of liquid crystals. The helical pitch of the materials is controlled by the ratio of the two materials and this in turn created the perceived colour pair. OPSEC Security (www.opsecurity.com) created a process which controls the pitch by controlling the amount of exposure to a given frequency of light. As the quantum of light increases, the colour shifts from one end of the spectrum to the other. It is envisaged that this effect is achieved through a greyscale mask being used to control the degree of light exposure.

All of these methods have certain drawbacks.

With the diffractive imagery method, the colour of the image varies as a function of viewing angle range. The diffraction efficiency varies as a function of pixel size and importantly when used in conjunction with a lens, the device only works when the diffractive gratings are at 90 degrees to the lens direction, i.e. it only works in conjunction with cylindrical lenses and not round lenses, limiting this effect to only one plane.

Plasmonic devices require highly conductive, metallic surfaces to work effectively. They are, typically, relatively low in colour strength and tend to produce subdue hues rather than vibrant colours. Their ability to be integrated into high-speed manufacturing process is limited due to the high aspect ratio of the structures as well as, typically, requiring to vacuum metallise the structure to achieve the required surface conductivity.

The current interference layer process requires the multi-layer refractive stack be produced using a magnetron deposition process. Then each individual pixel must be separately written using laser. This limits the technology to a batch process with a very slow throughput for writing (even though the laser can have relatively high speed write rates, a large number of pixels would require tens of seconds of writing for each image, if not minutes).

The UV cholesteric nematic pair via the light exposure route includes the added complexity of controlling the degree of light exposure not only through a mask but also the aging of the light source as a function of time. Any variance will result in the variance of the colour of the images. It requires the device to be exposed to be in registration with the surface of a material upon which it is deposited, which further complicates the manufacturing process.

At least preferred embodiments of the present invention provide an optical device and method for the formation thereof which addresses one or more limitations of the prior art, or at least provide an alternative choice for the general public.

### SUMMARY OF THE INVENTION

In a first aspect, the present invention provides an optical effect device comprising:

a substrate having a first surface and a second surface;

a plurality of structures arranged on the first surface, each structure having a first facet and a second facet, the first facet of each structure being substantially parallel to the first surface of the substrate, the second facet of each structure defining a slope with respect to the first surface, and the first facets of the plurality of structures forming a first facet set,

wherein the first facet set defines a first optical effect when the optical effect device is viewed from a first viewing angle range.

In an embodiment, each structure has a third facet and a fourth facet, the third facet of each structure is substantially parallel to the first surface of the substrate, the fourth facet of each structure faces in second direction and defines a slope with respect to the first surface of the substrate, the third facets of the plurality of structures forming a second facet set that defines a second optical effect when the optical effect device is viewed from a second viewing angle range.

In an embodiment, the optical effect device further comprises a surface structure disposed on one or more of the second facets and the fourth facets of the plurality of structures.

In an embodiment, the optical effect device further comprises a surface structure disposed on one or more of the first facets and the third facets of the plurality of structures.

In a second aspect, the present invention provides an optical effect device comprising:

a substrate having a first surface and a second surface;

a first plurality of structures arranged on the first surface of the substrate, the first plurality of structures having a first in-plane orientation with respect to the first surface of the substrate, each structure of the first plurality of structures having a facet that faces in a first direction, the facets of the first plurality of structures forming a first facet set; and

a second plurality of structures arranged on the first surface of the substrate, the second plurality of structures having a second in-plane orientation with respect to the first surface of the substrate, each structure of the second plurality of structures having a facet that faces in a second direction, the facets of the second plurality of structures forming a second facet set,

wherein the first facet set defines a first optical effect when the optical effect device is viewed from a first viewing angle range and the second facet set defines a second optical effect when the optical effect device is viewed from a second viewing angle range.

In an embodiment, the optical effect device further comprises a third plurality of structures arranged on the first surface of the substrate, the third plurality of structures having a third in-plane orientation with respect to the first surface of the substrate, each structure of the third plurality of structures having a facet that faces in a third direction, the facets of the third plurality of structures forming a third facet set that defines a third optical effect when the optical effect device is viewed from a third viewing angle range.

In an embodiment, each facet of each the first plurality of facets, the second plurality of facets, and the third plurality of facets defines a slope with respect to the first surface of the substrate.

In an embodiment:

the structures of the first plurality of structures are arranged at locations on the first surface of the substrate corresponding to pixels of the first optical effect;

the structures of the second plurality of structures are arranged at locations on the first surface of the substrate corresponding to pixels of the second optical effect; and

the structures of the third plurality of structures are arranged at locations on the first surface of the substrate corresponding to pixels of the third optical effect.

In an embodiment, the difference between the in-plane orientation of the first plurality of structures and the second plurality of structures is 120 degrees and the difference between the in-plane orientation of the second plurality of structures and the third plurality of structures is 120 degrees.

In an embodiment, the optical effect device further comprises a surface structure disposed on one or more of the facets of the first plurality of facets, the second plurality of facets, and/or the third plurality of facets.

In third aspect, the present invention provides an optical effect device comprising:

a substrate having a first surface and a second surface;

a plurality of structures arranged on the first surface, each structure having a first facet, the first facets of the plurality of structures forming a first facet set, and the first facet set defining a first optical effect when the optical effect device is viewed from a first viewing angle range,

wherein each structure corresponds to a pixel of the first optical effect, each pixel of the first optical effect having a scalar value corresponding to a shade of the pixel in the first optical effect, and each structure is modulated according to the scalar value of the respective pixel.

In an embodiment, the first facet of each structure defines a slope having an angle with respect to the first surface of the substrate and, for each structure, the angle of the slope of the first facet is modulated according to the scalar value of the respective pixel.

In an embodiment, wherein each structure has an in-plane orientation with respect to the first surface of the substrate and the in-plane orientation of each structure is modulated according to the scalar value of the respective pixel.

In an embodiment, the optical effect device further comprises a surface structure disposed on one or more of the first facets of the plurality of structures.

In an embodiment, each surface structure is a diffraction grating.

In a fourth aspect, the present invention provides an optical effect device comprising:

a substrate having a first surface and a second surface;

a first plurality of structures arranged on the first surface, each structure of the first plurality of structures having a first facet that faces in a first direction and a second facet that faces in a second direction, the first facets of the first plurality of structures forming a first facet set, and the second facets of the first plurality of structures forming a second facet set,

wherein the first facet set defines a first optical effect when the optical effect device is viewed from a first viewing angle range and the second facet set defines the first optical effect when the optical effect device is viewed from a second viewing angle range.

In an embodiment:

each structure of the first plurality of structures has a third facet;

for each structure of the first plurality of structures, the third facet faces in a third direction;

the third facets of the first plurality of structures form a third facet set; and

the third facet set defines the first optical effect when the optical effect device is viewed from a third viewing angle range.

In an embodiment, the optical effect device further comprises a second plurality of structures, each structure of the second plurality of structures having a first facet that faces in a fourth direction and a second facet that faces in a fifth direction, wherein:

the first facets of the second plurality of structures form a fourth facet set that defines a second optical effect when the optical effect device is viewed from a fourth viewing angle range; and

the second facets of the second plurality of structures form a fifth facet set that defines the second optical effect when the optical effect device is viewed from a fifth viewing angle range.

In an embodiment:

each structure of the second plurality of structures has a third facet;

for each structure of the second plurality of structures, the third facet faces in a sixth direction;

the third facets of the second plurality of structures form a sixth facet set; and

the sixth facet set defines the second optical effect when the optical effect device is viewed from a sixth viewing angle range.

In an embodiment:

the structures of the first plurality of structures are arranged at locations on the first surface of the substrate corresponding to pixels of the first optical effect; and

the structures of the second plurality of structures are arranged at locations on the first surface of the substrate corresponding to pixels of the second optical effect.

In an embodiment, the first plurality of structures has a first in-plane orientation with respect to the first surface of the substrate and the second plurality of structures has a second in-plane orientation with respect to the first surface of the substrate.

In an embodiment, the in-plane orientation of the first plurality of structures is perpendicular to the in-plane orientation of the second plurality of structures.

In an embodiment, each optical effect is viewable from viewing positions located on the same side as the first surface and the second surface of the substrate.

In an embodiment, each optical effect is viewable in reflectance and transmission.

In an embodiment, the substrate and each structure is formed from a transparent material.

In an embodiment, the substrate is formed from an opaque material.

In an embodiment, each structure is formed from a radiation curable resin.

In an embodiment, each structure is embossed into the radiation curable resin.

In an embodiment, the optical effect device further comprises a reflective layer disposed on the plurality of structures.

In an embodiment, the reflective layer is formed from a metallic ink.

In an embodiment, the optical effect device further comprises a protective layer disposed over the plurality of structures.

In an embodiment, the protective layer is a high refractive index layer.

In an embodiment, the reflective layer forms a first side of the optical effect device.

In an embodiment, the protective layer forms a first side of the optical effect device.

In an embodiment, the first side is planar.

In an embodiment, each optical effect is a binary or a dithered binary image.

In a fifth aspect, the present invention provides a security document comprising a security element in the form of an optical effect device according to any one of above aspects.

In an embodiment, the security device is disposed in a half window or full window of the security document.

In an embodiment, the security document is a bank note.

### Security Document or Token

As used herein the term security documents and tokens includes all types of documents and tokens of value and identification documents including, but not limited to the following: items of currency such as banknotes and coins, credit cards, cheques, passports, identity cards, securities and share certificates, driver's licenses, deeds of title, travel documents such as airline and train tickets, entrance cards and tickets, birth, death and marriage certificates, and academic transcripts.

The invention is particularly, but not exclusively, applicable to security documents or tokens such as banknotes or identification documents such as identity cards or passports formed from a substrate to which one or more layers of printing are applied. The diffraction gratings and optically variable devices described herein may also have application in other products, such as packaging.

### Security Device or Feature

As used herein the term security device or feature includes any one of a large number of security devices, elements or features intended to protect the security document or token from counterfeiting, copying, alteration or tampering. Security devices or features may be provided in or on the substrate of the security document or in or on one or more layers applied to the base substrate, and may take a wide variety of forms, such as security threads embedded in layers of the security document; security inks such as fluorescent, luminescent and phosphorescent inks, metallic inks, iridescent inks, photochromic, thermochromic, hydrochromic or piezochromic inks; printed and embossed features, including relief structures; interference layers; liquid crystal devices; lenses and lenticular structures; optically variable devices (OVDs) such as diffractive devices including diffraction gratings, holograms and diffractive optical elements (DOEs).

### Substrate

As used herein, the term substrate refers to the base material from which the security document or token is formed. The base material may be paper or other fibrous material such as cellulose; a plastic or polymeric material including but not limited to polypropylene (PP), polyethylene (PE), polycarbonate (PC), polyvinyl chloride (PVC), polyethylene terephthalate (PET); or a composite material of two or more materials, such as a laminate of paper and at least one plastic material, or of two or more polymeric materials.

### Windows and Half Windows

As used herein the term window refers to a transparent or translucent area in the security document compared to the substantially opaque region to which printing is applied. The window may be fully transparent so that it allows the transmission of light substantially unaffected, or it may be partly transparent or translucent partially allowing the transmission of light but without allowing objects to be seen clearly through the window area.

A window area may be formed in a polymeric security document which has at least one layer of transparent polymeric material and one or more opacifying layers applied to at least one side of a transparent polymeric substrate, by omitting least one opacifying layer in the region forming the window area. If opacifying layers are applied to both sides of a transparent substrate, a fully transparent window may be formed by omitting the opacifying layers on both sides of the transparent substrate in the window area.

A partly transparent or translucent area, hereinafter referred to as a “half-window”, may be formed in a polymeric security document which has opacifying layers on both sides by omitting the opacifying layers on one side only of the security document in the window area so that the “half-window” is not fully transparent, but allows some light to pass through without allowing objects to be viewed clearly through the half-window.

Alternatively, it is possible for the substrates to be formed from an substantially opaque material, such as paper or fibrous material, with an insert of transparent plastics material inserted into a cut-out, or recess in the paper or fibrous substrate to form a transparent window or a translucent half-window area.

### Opacifying Layers

One or more opacifying layers may be applied to a transparent substrate to increase the opacity of the security document. An opacifying layer is such that LT<Lo, where Lo is the amount of light incident on the document, and Li is the amount of light transmitted through the document. An opacifying layer may comprise any one or more of a variety of opacifying coatings. For example, the opacifying coatings may comprise a pigment, such as titanium dioxide, dispersed within a binder or carrier of heat-activated cross-linkable polymeric material. Alternatively, a substrate of transparent plastic material could be sandwiched between opacifying layers of paper or other partially or substantially opaque material to which indicia may be subsequently printed or otherwise applied.

### Refractive Index n

The refractive index of a medium n is the ratio of the speed of light in vacuum to the speed of light in the medium. The refractive index n of a lens determines the amount by which light rays reaching the lens surface will be refracted, according to Snell's law:

n₁*Sin(α)=n*Sin(θ)

where α is the angle between an incident ray and the normal at the point of incidence at the lens surface, θ is the angle between the refracted ray and the normal at the point of incidence, and n₁ is the refractive index of air (as an approximation n₁ may be taken to be 1).

### Radiation Curable Ink

The term radiation curable ink used herein refers to any ink, lacquer or other coating which may be applied to the substrate in a printing process, and which can be printed or embossed while soft, or semi-soft, to form a relief structure and cured by radiation to fix the relief structure. The curing process, typically, does not take place before the radiation curable ink is printed or embossed, but it is possible for the ink to be partially cured (semi-soft), in some processes, before printing or embossing and also for the curing process to take place either after printing or embossing or at substantially the same time as the printing or embossing step. The radiation curable ink is preferably curable by ultraviolet (UV) radiation. Alternatively, the radiation curable ink may be cured by other forms of radiation, such as electron beams or X-rays. References to UV curable ink(s) in the remainder of the description are by way of example. All embodiments may be replaceable with other radiation curable inks, as long as they can meet the criteria required by the embodiment (such as viscosity prior to curing). Similarly, reference to UV lamps reflect that the description refers to UV curable inks. If an ink curable by electron beam is used, then, clearly, an electron beam device would be used instead of the UV lamps.

The radiation curable ink is preferably a transparent or translucent ink formed from a clear resin material. Such a transparent or translucent ink is particularly suitable for printing light-transmissive security elements such as subwavelength gratings, transmissive diffractive gratings and lens structures.

The transparent or translucent ink preferably comprises an acrylic based UV curable clear lacquer or coating. Such UV curable lacquers can be obtained from various manufacturers, including Kingfisher Ink Limited, product ultraviolet type UVF-203 or similar. Alternatively, the radiation curable ink may be based on other compounds, eg nitro-cellulose.

The radiation curable inks and lacquers used herein have been found to be particularly suitable for printing or embossing microstructures, including diffractive structures such as diffraction gratings and holograms, and microlenses and lens arrays. However, they may also be printed or embossed with larger relief structures, such as non-diffractive optically variable devices.

The ink is preferably printed or embossed and cured by ultraviolet (UV) radiation at substantially the same time.

Preferably, in order to be suitable for Gravure printing, which is the preferred method of applying the radiation curable ink when it is subsequently embossed, the radiation curable ink has a viscosity falling substantially in the range from about 20 to about 175 centipoise, and more preferably from about 30 to about 150 centipoise. The viscosity may be determined by measuring the time to drain the lacquer from a Zahn Cup #2. A sample which drains in 20 seconds has a viscosity of 30 centipoise, and a sample which drains in 63 seconds has a viscosity of 150 centipoise.

With some polymeric substrates, it may be necessary to apply an intermediate layer to the substrate before the radiation curable ink is applied to improve the adhesion of the structure formed by the ink to the substrate. The intermediate layer preferably comprises a primer layer, and more preferably the primer layer includes a polyethylene imine. The primer layer may also include a cross-linker, for example a multi-functional isocyanate. Examples of other primers suitable for use in the invention include: hydroxyl terminated polymers; hydroxyl terminated polyester based co-polymers; cross-linked or uncross-linked hydroxylated acrylates; polyurethanes; and UV curing anionic or cationic acrylates. Examples of suitable cross-linkers include: isocyanates; polyaziridines; zirconium complexes; aluminium acetylacetone; melamines; and carbodi-imides.

### BRIEF DESCRIPTION OF THE DRAWINGS

Preferred embodiments of the invention will now be described, by way of examples only, with reference to the accompanying drawings. It is to be appreciated that the embodiments are given by way of illustration only and the invention is not limited by this illustration. In the drawings:

FIG. 1 is an isometric view of an optical effect device according to a first embodiment of the present invention;

FIG. 2 is a side view of the optical effect device of FIG. 1;

FIG. 3 is an example of an optical effect projected by the optical effect device of FIG. 1;

FIG. 4 is another example of an optical effect projected by the optical effect device of FIG. 1;

FIG. 5 is a variation of the optical effect device of FIG. 1;

FIG. 6 is another variation of the optical effect device of FIG. 1;

FIG. 7 is another variation of the optical effect device of FIG. 1;

FIGS. 8A-B illustrate how the maximum thickness of the structures of the optical effect device of Figure may be reduced;

FIG. 9 is a top view of a physical embodiment of the optical effect device of FIG. 1;

FIG. 10 is a top view of another physical embodiment of the optical effect device of FIG. 1;

FIG. 11 is a top view of another physical embodiment of the optical effect device of FIG. 1;

FIG. 12 is an isometric view of an optical effect device according to a second embodiment of the present invention;

FIG. 13 is a top view of the optical effect device of FIG. 12;

FIG. 14 shows the general viewing angle ranges of the optical effects of the optical effect device of FIG. 12;

FIG. 15 is a top view of an optical effect device according to a third embodiment of the present invention;

FIG. 16 is a cross sectional view of the optical effect device of FIG. 15 through the line 15-15 in FIG. 15;

FIG. 17 is a variation of the optical effect device of FIG. 15;

FIG. 18 is another variation of the optical effect device of FIG. 15;

FIG. 19 is a top view of an optical effect device according to a fourth embodiment of the present invention;

FIG. 20 is a cross sectional view of the optical effect device of FIG. 19 through the line 19-19 in FIG. 19;

FIG. 21 is a top view of an optical effect device according to fifth embodiment of the present invention;

FIG. 22 is an enlarged top view of the optical effect device of FIG. 21;

FIG. 23 is a top view of an optical effect device according to a sixth embodiment of the present invention;

FIG. 24 is a cross sectional view of the optical effect device of FIG. 23 through the line 23-23 in FIG. 23;

FIG. 25 is a top view of an optical effect device according to a seventh embodiment of the present invention;

FIG. 26 is a partial side view of the optical effect device of FIG. 25;

FIG. 27 is a top view of one of the structures of the optical effect device of FIG. 25;

FIG. 28 is an isometric view of the structure of FIG. 27;

FIGS. 29A-B show the black and white pixels of each of the two optical effects produced by the arrangement of structures shown in FIG. 25;

FIG. 30 illustrates how multiples of the structure of FIG. 26 may be arranged in the optical effect device of FIG. 25 to produce a three-switch optical effect;

FIG. 31 is a top view of an optical effect device according to an eighth embodiment of the present invention;

FIG. 32 shows the viewing angles ranges and the projection angle ranges of the structures of the optical effect device of FIG. 31;

FIG. 33 shows the projection angles of the image channels of the optical effect device of FIG. 31;

FIG. 34 is a side view of the optical effect device of FIG. 1 having a clear protective layer or reflective layer disposed over the structures, where the clear protective layer or reflective layer defines a planar side of the optical effect device of FIG. 1; and

FIG. 35 is a security document having a security device, the security device being any one of the optical effect devices disclosed herein.

### DESCRIPTION OF PREFERRED EMBODIMENT

For the purposes of the following discussion, the figures are to be considered illustrative and not to scale, unless otherwise indicated. The figures illustrate simplified depictions of the embodiments described.

“Incident light” or “Incident illumination” is light from a light source incident onto a side of the substrate, and is in general considered to be non-polarised white light (for example, as sourced from an incandescent or fluorescent light source), unless otherwise stated.

A “visual effect” is an image, pattern, or other visually identifiable effect. A visual effect can be a hidden visual effect, which is only visible under certain conditions, or an overt visual effect, which is visible under normal viewing conditions. A visual effect can also be a diffractive visual effect or a non-diffractive visual effect.

“Colour” as used herein refers to a colour as perceived and may correspond to a single range of wavelengths or a mixing of different ranges of wavelengths.

It should be noted that throughout the present disclosure, ‘multicolour’ is used to mean at least two different colours, and preferably, a broad range of different colours. In addition, if a polarisation image shows, for example a motif, a number, or an icon, then the motif, number or icon itself must include a plurality of different colours in order to be considered as a multicolour image.

### First Exemplary Embodiments of the Invention

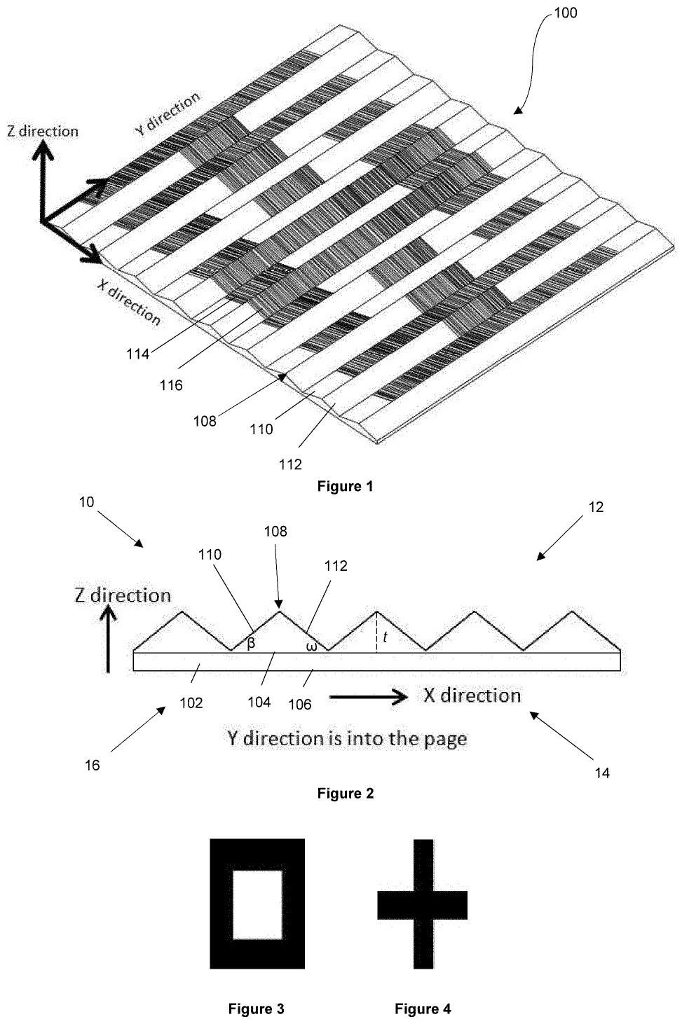

FIG. 1 shows an optical effect device 100 in the form of a security device according to a first embodiment of the present invention. Referring to FIG. 2, the optical effect device 100 comprises a substrate 102 having a first surface 104 and a second surface 106.

Arranged on the first surface 104 of the substrate 102 is a plurality of structures 108 having a maximum thickness t. Each structure 108 has a first facet 110 facing in a first direction and a second facet 112 facing in a second direction that is different to the first direction. The first facets 110 of the plurality of structures 108 together form a first facet set that defines a first image channel having a first projection angle range and the second facets 112 of the plurality of structures 108 form a second facet set that defines a second image channel having a second projection angle range. The first facet 110 of each structure 108 is adjacent the second facet 112 of an adjacent structure 108 such that the first facets 110 are interleaved with the second facets 112. Each first facet 110 defines a slope having an angle β with respect to the first surface 104 of the substrate 102 and each facet 112 defines a slope having an angle ω with respect to the first surface 104 of the substrate 102.

Disposed on each first facet 110 is one or more diffraction gratings 114 and disposed on each second facet 112 is one or more diffraction gratings 116. As best seen in FIG. 1, the lines of the diffraction gratings 114, 116 extend parallel to the direction of maximum slope of the respective facet 110, 112. In other words, the lines of the diffraction gratings 114 disposed on the first facets 110 extend in a direction parallel to the angle β and the lines of the diffraction gratings 116 disposed on the second facets 112 extend in a direction parallel to the angle ω. It is also envisaged however that the lines of each diffraction grating 114, 116 may be oriented in other directions depending on the desired viewing angle ranges of the respective first and second image channels, for example, in a direction extending along the length of the respective facet 110, 112 (e.g., in the Y direction in FIG. 1) or at an angle with respect to the direction of maximum slope of the respective facet 110, 112.

Referring to FIGS. 1, 2, and 3, when the first facet set is viewed from a first viewing angle range generally indicated by the arrow 10, the diffraction gratings 114 disposed on the first facets 110 define a first optical effect, for example, a rectangular shape as illustrated in FIG. 3. Referring to FIGS. 1, 2, and 4, when the second facet set is viewed from a second viewing angle range generally indicated by the arrow 12, the diffraction gratings 116 disposed on the second facets 112 define a second optical effect, for example, a cross as illustrated in FIG. 4. It will be appreciated that the first and second optical effects may be any desired image.

As best seen in FIG. 2, the first viewing angle range 10 and the second viewing angle range 12 provide for viewing positions that are located on the same side as the first surface 104 of the substrate 102. The first optical effect and the second optical effect may also be viewable from viewing positions located on the same side as the second surface 106 of the substrate 102, if the substrate 102 and the structures 108 are formed from a transparent material. In this case, the first and second optical effects are viewable from the same side as the second surface 106 from viewing positions having a viewing angle range generally indicated by the arrows 14 and 16, respectively.

The optical effect device 100 therefore interleaves two images (i.e., the first and second optical effects) that can be projected to an observer at a corresponding one-dimensional array of viewing angle ranges, thereby providing sampling of the first and second optical effects along a single axis. It will therefore be appreciated that the optical effect device 100 provides a 2-flip optical effect.

It is also envisaged that only the facets of one of the facet sets (i.e., image channels) may have diffraction gratings. In this case, it will be appreciated that the optical effect device 100 provides a disappearing image effect.

The general structure of embodiments of the optical effect device 100 are outlined below:
The structures 108 may be formed from a transparent material, for example, a radiation curable resin (discussed in more detail below);
The substrate 102 may also be transparent and may be formed as a foil (such as for application to a security document) or a polymer substrate (e.g., a banknote polymer substrate);
The structures 108 may be overcoated with a clear protective layer that may have a different refractive index to that of the material used to form the structures 108. The clear protective layer may be sufficiently thick to prevent mechanical copying (i.e. contact copying) of the structures 108 (discussed in more detail below); and
Alternatively, the structures 108 may be overcoated with a reflective layer. The reflective layer may be sufficiently thick to prevent mechanical copying (i.e. contact copying) of the structures 108. Alternatively, the reflective layer may be thin and overcoated with a clear protective layer that is sufficiently thick to prevent mechanical copying (i.e., contact copying) of the structures 108.

If the structures 108 are not overcoated with a reflective layer or are overcoated with a semi-transparent reflective layer, the first and second optical effects may be viewed in both transmission and reflectance. In this case, the first optical effect may be viewable from viewing positions located on the same side as the first surface 104 having viewing angle ranges generally indicated by the arrows 10 and 12, respectively (see FIG. 2). Similarly, the second optical effect may be viewable from viewing position located on the same side as the second surface 106 having viewing angle ranges generally indicated by the arrows 14 and 16, respectively (see FIG. 2). This will also be the case if the structures 108 are overcoated with a thin reflective layer (e.g., less than the maximum thickness of the structures 108, but sufficiently thick to substantially prevent transmission of light), however, in this case, the first and second optical effects will only be viewable in reflected light.

If the structures 108 are overcoated with a thick reflective layer such that mechanical copying of the structures 108 may be prevented/restricted, the first and second optical effects will only be viewable in reflectance from viewing positions located on the same side as the second surface 106 having viewing angle ranges generally indicated by the arrows 14 and 16, respectively (see FIG. 2).

If the structures 108 are not overcoated with a reflective layer, when the optical effect device 100 is viewed in reflected or transmitted diffuse white light, the first and second optical effects are observed in black and white and, as the optical effect device 100 is rotated about the Y axis, or offset from the light source, the optical effects viewed transition between the first and second optical effects. When the optical effect device 100 is viewed in reflected or transmitted white light that is at least partially collimated, or from a point source, the first and second optical effects are observed in multiple colours and, as the optical effect device 100 is rotated about the Y axis, or offset from the light source, the optical effects viewed transition between the first and second optical effects.

Through the appropriate selection of grating frequency, depth, and orientation of the lines of the diffraction gratings 114, 116, the first and second optical effects projected by the respective first and second image channels at a particular angle can be a true colour image. For example, the grating frequency, depth, and orientation of the lines of the diffraction gratings 114, 116 can be selected such that they project a two-dimensional array of RGB coloured image pixels such that the first and second facet sets each define a desired full colour image intended to be observed at a particular angle with substantially collimated white light. The images defined by the respective diffraction gratings 114, 116 of each facet set could have multiple tones of one or more desired colours.

It is also envisaged that the substrate 102 may be formed from an opaque material (e.g., a foil or a polymer of a banknote) and that the structures 108 may be formed from a transparent material (e.g., a radiation curable resin). In this case, it will be appreciated that the optical effects will only be viewable in reflectance from viewing positions located on the same side as the first surface 104 of the substrate 102. The visibility of the optical effects in this case may be improved by overcoating the structures 108 with a thin reflective layer.

The diffraction gratings 114, 116 can be disposed on the respective first and second facets 110, 112 such that the first and/or second image channels define:
a monochromatic ‘silhouette’ binary image;
a binary dithered halftone image; or
a dithered binary image.

According to an embodiment of the optical effect device 100, each structure 108 has a maximum thickness t of 6 microns and each facet 110, 112 may have a width of 25 microns. It is envisaged however that the structures 108 and the facets 110, 112 may have other dimensions. Each diffraction grating 114, 116 may have a period of 1.2 μm to 3.2 μm, however, other periods are also envisaged depending on the desired colours to be viewed from the respective diffraction gratings 114, 116.

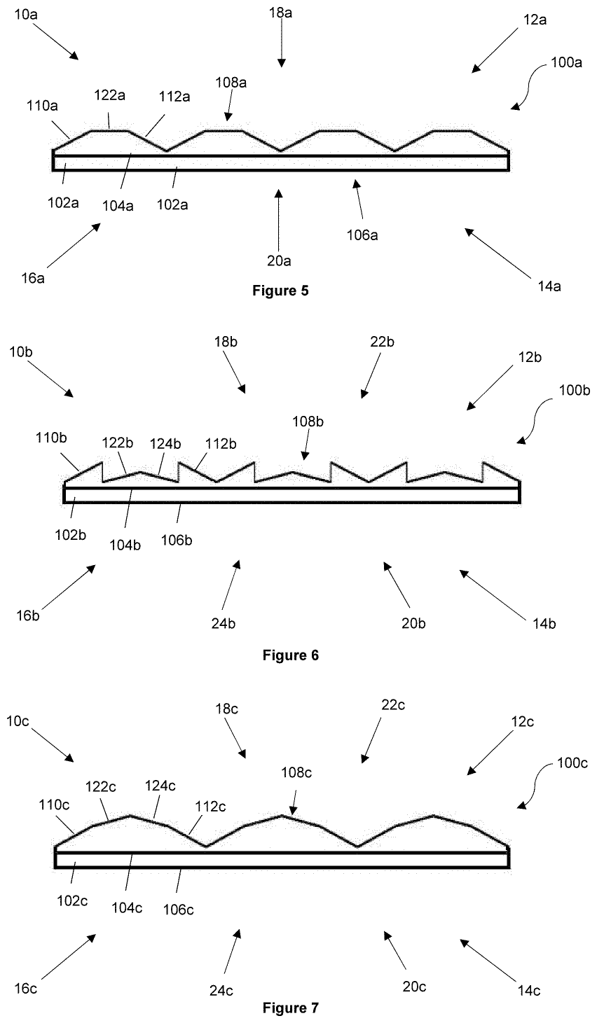

FIG. 5 shows an optical effect device 100a that is similar to the optical effect device 100, except that each structure 108a of the optical effect device 100a has a third facet 122a facing in a third direction that is different to the first and second directions. The third facets 122a of the plurality of structures 108a together form a third facet set that defines a third image channel having a third projection angle range. Similar to that described above with respect to the optical effect device 100, at least one diffraction grating may be disposed on one or more of the third facets 122a such that the third facet set defines a third optical effect when viewed from the same side as the first surface 104a from a viewing position having a viewing angle range generally indicated by the arrow 18a. The third viewing angle range 18a is different to the first and second viewing angle ranges. Similar to the optical effect device 100, if the substrate 102a and the structures 108a are formed from a transparent material, the third optical effect may be viewable from the same side as the second surface 106a from a viewing position having a viewing angle range generally indicated by the arrow 20a.

FIG. 6 shows an optical device 100b that is similar to the optical effect device 100, except that each structure 108b of the optical effect device 100b has a third facet 122b facing in a third direction and a fourth facet 124b facing in a fourth direction. The third direction and the fourth direction being different to each other and the first and second directions. The third facets 122b of the plurality of structures 108b together form a third facet set that defines a third image channel having a third projection angle and the fourth facets 124b of the plurality of structures 108b together form a fourth facet set that defines a fourth image channel having a fourth projection angle. Similar to that described above with respect to the optical device 100, at least one diffraction grating may be disposed on one or more of the third facets 122b and the fourth facets 124b.

The third facet set of the optical effect device 100b defines a third optical effect when viewed from the same side as the first surface 104b from a viewing position having a viewing angle range generally indicated by the arrow 18b. The fourth facet set of the optical effect device 100b defines a fourth optical effect when viewed from the same side as the first surface 104b from a viewing position having a viewing angle range generally indicated by the arrow 22b. The third viewing angle range and the fourth viewing angle range being different to each other and the first and second viewing angle ranges. Similar to the optical effect device 100, if the substrate 102b and the structures 108b are formed from a transparent material, the third and fourth optical effects may be viewable from the same side as the second surface 106b from viewing positions having viewing angle ranges generally indicated by the arrow 20b and the arrow 24b, respectively.

Other structural variations discussed in relation to FIGS. 1 to 4, particularly in relation to the properties of the substrate and structure layers and the presence or otherwise of various protective and/or refractive/reflective layers are equally applicable to the embodiments of FIGS. 5 and 6, and in need to all other embodiments discussed below.

FIG. 7 shows an optical effect device 100c that is similar to the optical effect device 100b, expect that the configuration of the structures 108c of the optical effect device 100c is different to the configuration of the structures 108b of the optical effect device 100b. In particular, the configuration of the first facet 110c, the second facet 112c, the third facet 122c, and the fourth facet 124c of each structure 108c is different to the configuration of the first facet 110b, the second facet 112b, the third facet 122b, and the fourth facet 124b of each structure 108b, respectively. The operation, behavior of the optical effects, and viewing angle ranges of the optical effects of the optical effect device 100c is similar to that of the optical effect device 100b.

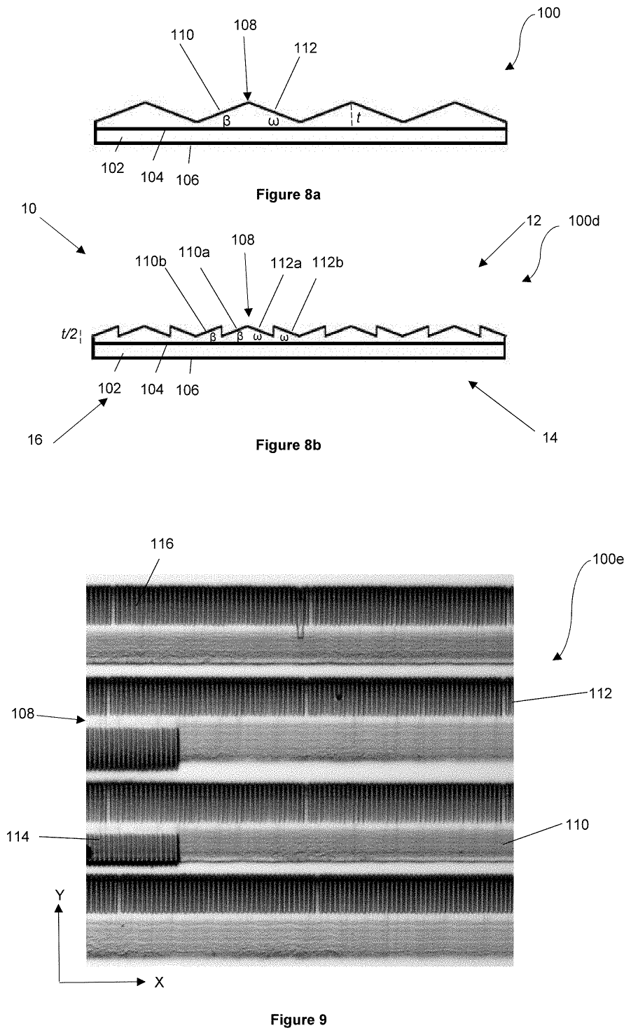

FIGS. 8a and 8b show the optical effect device 100 and an optical effect device 100d, respectively. FIGS. 8a and 8b, illustrate how the maximum thickness t of each structure 108 may be reduced. Referring to FIG. 8b, each facet 110 of FIG. 8a is divided into two smaller facets 110a,110b and each facet 112 of FIG. 8a is divided into two smaller facets 112a, 112b. The angle β of the slope defined by each facet 110a, 110b in FIG. 8b is equal to the angle β of the slope defined by each facet 110 in FIG. 8a. The angle ω of the slope defined by each facet 112a, 112b in FIG. 8b is equal to the angle ω of the slope defined by each facet 112 in FIG. 8a. The facets 110a, 110b define the first image channel and the facets 112a, 112b define the second image channel. The operation, behavior of the optical effects, and viewing angle ranges of the optical effects of the optical effect device 100d is similar to the optical effect device 100. It will be appreciated that the maximum thickness of the structures 108 of the optical effect device 100 may be reduced further by dividing the facets 110, 112 into more than two smaller facets.

According to an embodiment of the optical effect device 100d, each structure 108 has a maximum thickness of 3 microns and each facet 110a-b, 112a-b has a width of 12.5 microns.

### Practical Examples of the Optical Effect Device 100

FIG. 9 shows a first practical example of the optical effect device 100e in which the first image channel (i.e., the first facets 110) and the second image channel (i.e., the second facets 112) each define a monochromatic ‘silhouette’ binary image. The lines of the diffraction gratings 114, 116 extend in a direction parallel to the direction of maximum slope of the respective facet 110, 112.

If the structures 108 are not overcoated with a reflective layer, when viewing the optical effect device 100e in transmission with the structures 108 oriented horizontally (i.e., extending along the X axis), a 2-flip optical effect is observed by moving the optical effect device 100e up or down in the Y direction, or left to right in the X direction, off axis from a light source. When viewing the optical effect device 100e in reflection with the structures 108 oriented horizontally (i.e., extending along the X axis), a 2-flip optical effect is observed by tilting the optical effect device 100e about the X axis. In both transmission and reflection, when observing the first and second optical effects of the optical effect device 100e, the first and second optical effects appear greyscale when viewed in diffuse white light and appear in multiple colours when viewed in at least partially collimated white light or white light from a point source.

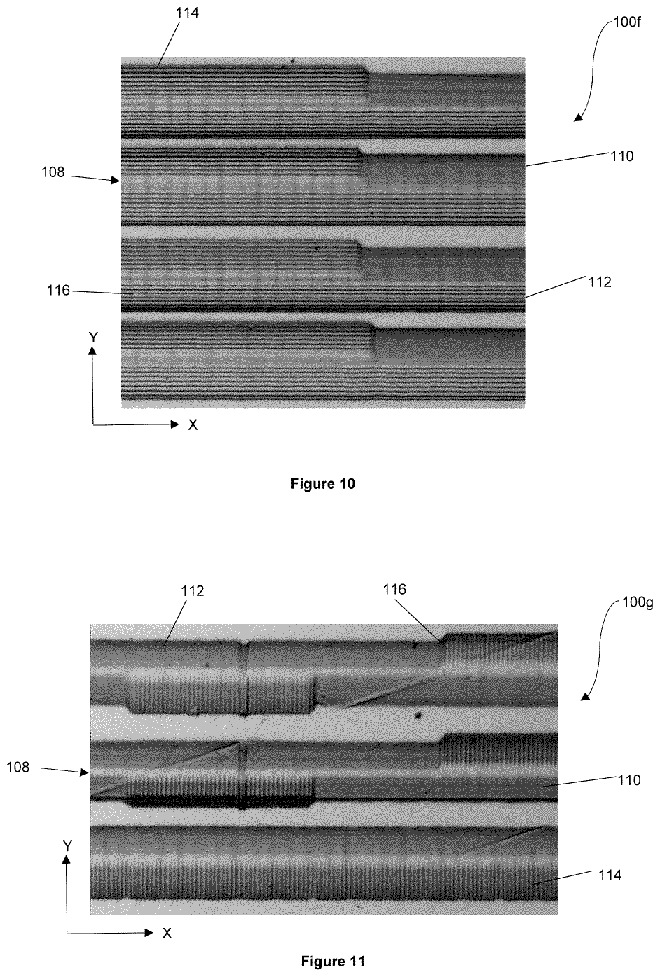

FIG. 10 shows a second practical example of the optical effect device 100f in which the first image channel (i.e., the first facets 110) and the second image channel (i.e., the second facets 112) each define a monochromatic ‘silhouette’ binary image. The lines of the diffraction gratings 114, 116 extend in a direction perpendicular to the direction of maximum slope of the respective facets 110, 112 (i.e., in the X direction along the length of the respective facet 110, 112). The behavior of the first and second optical effects of the optical effect device 100f is similar to the behavior of the first and second optical effects of the optical effect device 100e. However, the colour contrast of the first and second optical effects of the optical effect device 100f was lower compared to the colour contrast of the first and second optical effects of the optical effect device 100e.

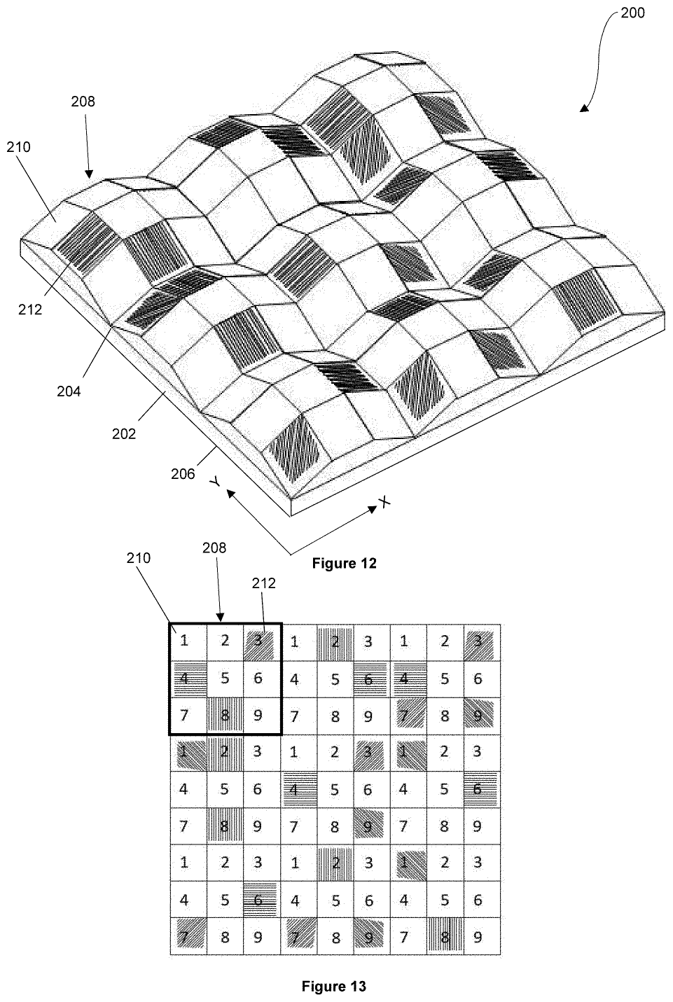

FIG. 11 shows a third practical example of the optical effect device 100g in which the first image (i.e., the first facets 110) and the second image channel (i.e., the second facets 112) each define a binary dithered halftone image. The behavior of the first and second optical effects of the optical effect device 100g is similar to the behavior of the first and second optical effects of the optical effect device 100e.

If the structures 108 are not overcoated with a reflective layer, when viewing the optical effect device 100g in both transmission and reflectance, the first and second optical effects of the optical effect device 100g contain multiple grey tones when viewed in diffuse white light and multiple colour tones when viewed in at least partially collimated white light. The multiple grey and colour tones viewable in the first and second optical effects of the optical effect device 100g is achievable by using dithered halftone image designs.

### Second Exemplary Embodiment of the Invention

FIG. 12 shows an optical effect device 200 in the form of a security device according to a second embodiment of the present invention. The optical effect device 200 comprises a substrate 202 having a first surface 204 and a second surface 206.

Arranged on the first surface 204 of the substrate 202 is a plurality of structures 208, each structure 208 having nine facets 210. Each facet 210 of each structure 208 faces in a different direction and has a unique slope and/or orientation (i.e., unique vector gradient) with respect to the first surface 204 of the substrate 202.

FIG. 13 is a top view of the optical effect device 200 in which each facet 210 of each structure 208 has been numbered 1 to 9. The facets 210 having the same number all face in the same direction to form a facet set that defines an image channel having a unique projection angle range. For example, the facets 210 numbered “1” in the plurality of structures 208 all face in the same direction to form a first facet set that defines a first image channel having a first projection angle range. It will therefore be appreciated that the optical effect device 200 has nine facet sets that each define an image channel having a unique projection angle range.

Disposed on one or more facets 210 of each facet set is a diffraction grating 212. The lines of each diffraction grating 212 extend in a direction parallel to the slope of the respective facet 210. In other words, the lines of each diffraction grating 212 extend in the direction of maximum slope of the respective facet 210. It also is envisaged however that the lines of each diffraction grating 212 could be oriented in other directions depending on the desired viewing angle ranges of the respective image channels, for example, in a direction extending perpendicular or at an angle with respect to the direction of maximum slope of the respective facet 210. Each diffraction grating 212 may have a period of 1.2 μm to 3.2 μm, however, other periods are also envisaged depending on the desired colours to be viewed from the respective diffraction gratings 212. It is also envisaged that all the facets 210 of one or more of the facet sets may not have any diffraction gratings 212.

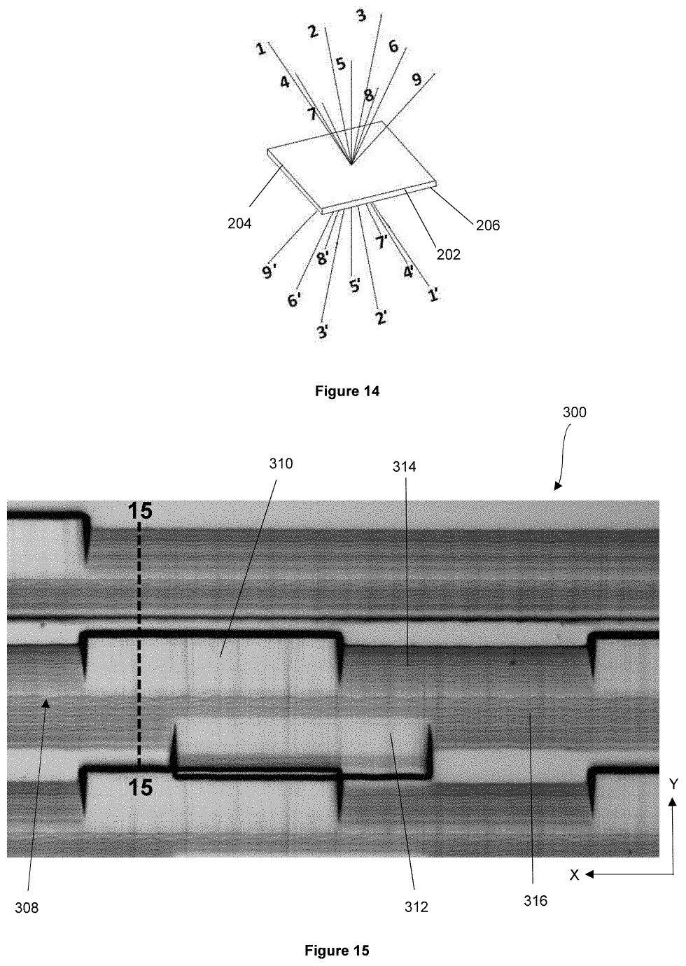

Referring to FIGS. 12 and 14, each image channel has a unique viewing angle range. For example, the first image channel (i.e., the facets 210 labelled “1” in each of the structures 208) has a viewing angle range generally indicated by the line numbered “1” in FIG. 14. Accordingly, each of the lines numbered 1 to 9 in FIG. 14 indicate a general viewing angle range for each respective image channel.

When each image channel is viewed from their respective viewing angle range, the diffraction gratings 212 disposed on the one or more facets 210 of the respective facet set define an optical effect. For example, when the first image channel (i.e., the facets 210 labelled “1” in each of the structures 208) is viewed from the first viewing angle range (i.e., generally indicated by the line numbered “1” in FIG. 14), the diffraction gratings 212 disposed on the one or more facets 210 of the first facet set define a first optical effect.

The optical effect device 200 therefore interleaves nine images in two dimensions (for example, in the X and Y dimensions) that can be projected to an observer at a corresponding array of viewing angle ranges, thereby allowing for the optical effects to be displayed when the device is rotated about more than one axis with respect to a light source.

The general structure of embodiments of the optical effect device 200 are outlined below:
The structures 208 may be formed from a transparent material, for example, a radiation curable resin (discussed in more detail below);
The substrate 202 may also be transparent and may be formed as a foil (such as for application to a security document) or a polymer substrate (e.g., a banknote polymer substrate);
The structures 208 may be overcoated with a clear protective layer that may have a different refractive index to that of the material used to form the structures 208. The clear protective layer may be sufficiently thick to prevent mechanical copying (i.e., contact copying) of the structures 208 (discussed in more detail below); and
Alternatively, the structures may be overcoated with a reflective layer. The reflective layer may be sufficiently thick to prevent mechanical copying (i.e., contact copying) of the structures 208. Alternatively, the reflective layer may be thin and overcoated with a clear protective layer that is sufficiently thick to prevent mechanical copying (i.e., contact copying) of the structures 208.

If the structures 208 are not overcoated with a reflective layer or are overcoated with a semi-transparent reflective layer, the optical effects may be viewed in both transmission and reflectance. In this case, the optical effects may be viewable from respective viewing positions located on the same side as the first surface 204 having viewing angle ranges generally indicated by the lines numbered 1 to 9 (see FIG. 14) and on the same side as the second surface 206 having viewing angle ranges generally indicated by the lines numbered 1′ to 9′ (see FIG. 14). This will also be the case if the structures 208 are overcoated with a thin reflective layer (e.g., less than the maximum thickness of the structures 208, but sufficiently thick to substantially prevent transmission of light), however, in this case, the optical effects will only be viewable in reflected light.

If the structures 208 are overcoated with a thick reflective layer such that mechanical copying of the structures 208 may be prevented/restricted, the optical effects will only be viewable in reflectance from viewing positions located on the same side as the second surface 206 having viewing angle ranges generally indicated by the lines numbered 1′ to 9′ (see FIG. 14).

If the structures 208 are not overcoated with a reflective layer, when viewing the optical effect device 200 in reflected or transmitted diffuse white light, the optical effects are observed in black and white and, as the optical effect device 200 is rotated about the X and/or Y axes, or offset from the light source, the optical effects viewed transition according to the relevant viewing angle range. When viewing the optical effect device 200 in reflected or transmitted white light that is at least partially collimated, or from a point source, the optical effects are observed in multiple colours and, as the optical effect device 200 is rotated about the about the X and/or Y axes, or offset from the light source, the optical effects viewed transition according to the relevant viewing angle range.

Through the appropriate selection of grating frequency, depth, orientation of the lines of the diffraction gratings 212, the optical effects projected by each facet set of the optical effect device 200 at a particular angle can be a true colour image. For example, the grating frequency, the depth, and orientation of the lines of the diffraction gratings 212 can be selected such that they project a two-dimensional array of RGB coloured image pixels such that each facet set of the optical effect device 200 defines a desired full colour image intended to be observed at a particular angle with substantially collimated white light. The image defined by the diffraction gratings 212 of each facet set of the optical effect device 200 could have multiple tones of one or more desired colours.

It is also envisaged that the substrate 202 may be formed from an opaque material (e.g., a foil or a polymer of a banknote) and that the structures 208 may be formed from a transparent material (e.g., a radiation curable resin). In this case, it will be appreciated that the optical effect will only be viewable in reflectance from viewing positions located on the same side as the first surface 204 of the substrate 202. The visibility of the optical effects in this case may be improved by overcoating the structures 208 with a thin reflective layer.

The diffraction gratings 212 can be disposed on one or more facets 210 of each facet set such that the respective image channel defines:
a monochromatic ‘silhouette’ binary image;
a binary dithered halftone image; or
a dithered binary image.

Although the structures 208 of the optical effect device 200 have been described and illustrated as having nine facets 210, it will be appreciated that the structures 208 of the optical effect device 200 may have more, or less, than nine facets 210.

It is also envisaged that the thickness of each structure 208 may be reduced using the approach described above with respect to the optical effect device 100d.

### Third Exemplary Embodiment of the Invention

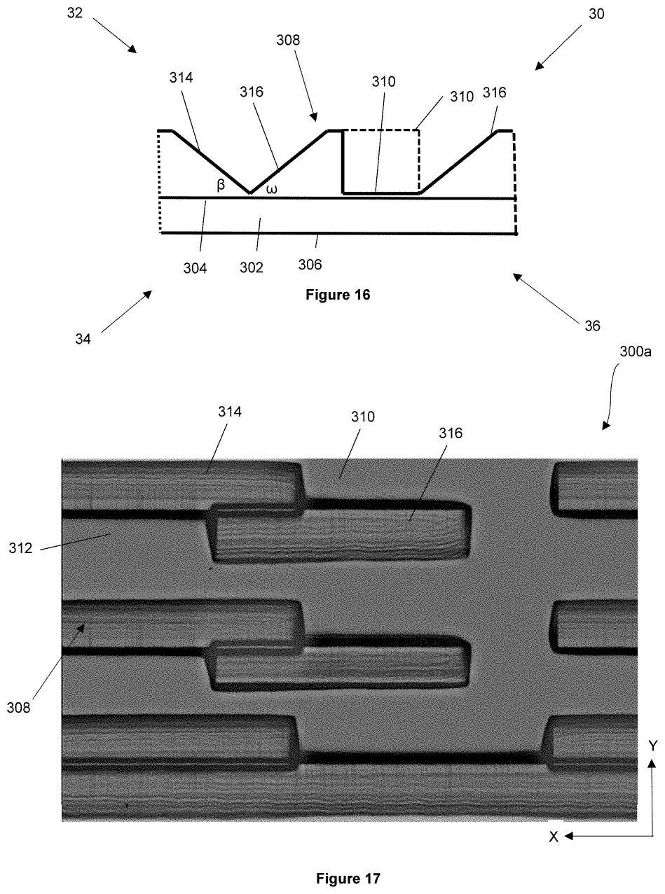

FIGS. 15 and 16 show a top view and a cross section of an optical effect device 300 in the form of a security device according to a third embodiment of the present invention, respectively. The optical effect device 300 comprises a substrate 302 having a first surface 304 and a second surface 306.

Arranged on the first surface 304 of the substrate 302 is a plurality of structures 308. Each structure 308 has one or more first facets 310, one or more second facets 312, a third facet 314, and a fourth facet 316. For each structure 308, the first facet(s) 310 and the second facet(s) 312 are substantially parallel to the first surface 304 of the substrate 302 and face in a first direction. In other words, each of the first facets 310 and each of the second facets 312 do not define a slope with respect to the first surface 304 of the substrate 302. All the first facets 310 of all the structures 308 together form a first facet set that defines a first image channel and all the second facets 312 of all the structures 308 together form a second facet set that defines a second image channel. FIG. 16 shows that the first facets 310 of each structure 308 are disposed at the bottom of the structure 308. Similarly, the second facets 312 of each structure 308 are also disposed at the bottom of the structure 308.

For each structure 308, the third facet 314 faces in a second direction and the fourth facet 316 faces in a third direction. As best seen in FIG. 16, the first, second, and third directions are all different to each other. For each structure 308, the third facet 314 defines a slope having an angle β with respect to the first surface 304 of the substrate 302 and the fourth facet 316 defines a slope having an angle ω with respect to the first surface 304 of the substrate 302.

When the first facet set is viewed from a first viewing angle range generally indicated by the arrow 30 in FIG. 16, the first facet set defines a first optical effect and, when the second facet set is viewed from a second viewing angle range generally indicated by the arrow 32 in FIG. 16, the second facet set defines a second optical effect. Referring to FIG. 16, the first viewing angle range 30 and the second viewing angle range 32 provide for viewing positions that are located on the same side as the first surface 304 of the substrate 302.

The general structure of embodiments of the optical effect device 300 are outlined below:
The structures 308 may be formed from a transparent material, for example, a radiation curable resin (discussed in more detail below);
The substrate 302 may also be transparent and may be formed as a foil (such as for application to a security document) or a polymer substrate (e.g., a banknote polymer substrate);
The structures 308 may be overcoated with a clear protective layer that may have a different refractive index to that of the material used to form the structures 308. The clear protective layer may be sufficiently thick to prevent mechanical copying (i.e., contact copying) of the structures 308 (discussed in more detail below); and
Alternatively, the structures 308 may be overcoated with a reflective layer. The reflective layer may be sufficiently thick to prevent mechanical copying (i.e., contact copying) of the structures 308. Alternatively, the reflective layer may be thin and overcoated with a clear protective layer that is sufficiently thick to prevent mechanical copying (i.e., contact copying) of the structures 308.

If the structures 308 are not overcoated with a reflective layer or are overcoated with a semi-transparent reflective layer, the first and second optical effects may be viewed in both transmission and reflectance. In this case, the first optical effect may be viewable from viewing positions located on the same side as the first surface 304 having viewing angle ranges generally indicated by the arrows 30 and 32, respectively (see FIG. 16). Similarly, the second optical effect may be viewable from viewing position located on the same side as the second surface 306 having viewing angle ranges generally indicated by the arrows 34 and 36, respectively (see FIG. 16). This will also be the case if the structures 308 are overcoated with a thin reflective layer (e.g., less than the maximum thickness of the structures 308, but sufficiently thick to substantially prevent transmission of light), however, in this case, the first and second optical effects will only be viewable in reflected light.

If the structures 308 are overcoated with a thick reflective layer such that mechanical copying of the structures 308 may be prevented/restricted, the first and second optical effects will only be viewable in reflectance from viewing positions located on the same side as the second surface 306 having viewing angle ranges generally indicated by the arrows 34 and 36, respectively (see FIG. 16).

Each first facet 310 and each second facet 312 may correspond to a foreground pixel (picture element), or a background pixel, of a binary image design. The first and second optical effects (i.e., images) may be derived by applying a dithering algorithm. For example, amplitude modulation or frequency modulation dithering can be used to input a greyscale image, which may enable high contrast optical effects to be projected with simulated greyscale to the observer.

The first and second optical effects of the optical effect device 300 can be projected to an observer at a corresponding one-dimensional array of viewing angle ranges, thereby providing sampling of the optical effects along a single axis. It will therefore be appreciated that the optical effect device 300 provides a 2-flip optical effect.

When viewing the optical effect device 300 in reflected or transmitted diffuse white light, the first and second optical effects are observed in black and white and, as the optical effect device 300 is rotated and/or tilted with respect to a light source, the optical effects viewed transition between the first and second optical effects.

It is also envisaged that the optical effect device 300 may project a plurality of optical effects to an observer over a two-dimensional array of viewing angle ranges by implementing the structures 308 to have a similar shape and configuration as the structures 208 illustrated in FIG. 12. For example, in this case, the structures 308 will be similar to the structures 208 but will have one or more facets 210 of each facet set being substantially parallel to the first surface 304 of the substrate 302.

Although FIG. 16 shows that the first facets 310 are disposed at the bottom of each structure 308, as indicated by the continuous line, it is also envisaged that the first facets 310 may be disposed at the top of each respective structure 308, as indicated by the broken lines. Similarly, the second facets 312 may also be disposed at the top of each respective structure 308. FIG. 17 shows a top view of an optical effect device 300a that is similar to the optical effect device 300, except that the first facets 310 and the second facets 312 of each structure 308 of the optical effect device 300a are disposed at the top of each respective structure 308. The optical behavior of the first and second optical effects of the optical effect device 300a is similar to, if not the same as, the optical behavior of the first and second optical effects of the optical effect device 300.

It is also envisaged that the substrate 302 may be formed from an opaque material (e.g., a foil or a polymer of a banknote) and that the structures 308 may be formed from a transparent material (e.g., a radiation curable resin). In this case, it will be appreciated that the optical effects will only be viewable in reflectance from viewing positions located on the same side as the first surface 304 of the substrate 302. The visibility of the optical effects in this case may be improved by overcoating the structures 308 with a thin reflective layer.

Each image channel of the optical effect device 300, 300a may be arranged to define:
a monochromatic ‘silhouette’ binary image;
a binary dithered halftone image; or
a dithered binary image.

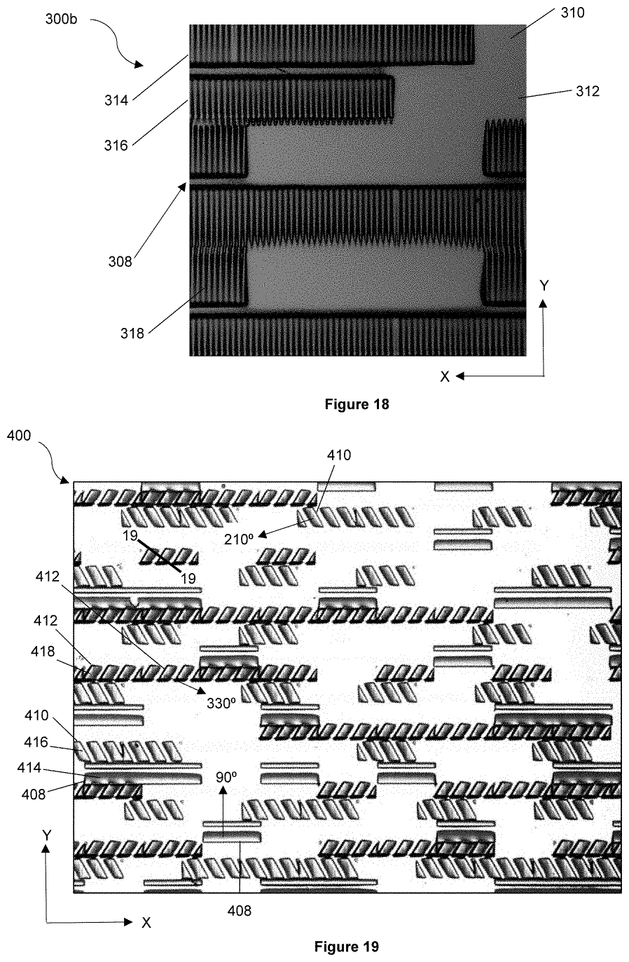

FIG. 18 shows an embodiment of an optical effect device 300b that is similar to the optical effect device 300a, except that diffraction gratings 318 are disposed on the third facets 314 and fourth facets 316 of the structures 308 of the optical effect device 300b. The lines of the diffraction grating 318 extend in a direction parallel to the slope of the respective facet 314, 316. In other words, the lines of each diffraction grating 318 extend in the direction of maximum slope of the respective facet 314, 316. It is also envisaged however that the lines of each diffraction grating 318 could be oriented in other directions depending on the desired colours to be projected in the viewing angle ranges of the respective first and second image channels, for example, in a direction extending perpendicular or at an angle with respect to the direction of maximum slope of the respective facet 314, 316. Each diffraction grating 318 may have a period of 1.2 μm to 3.2 μm, however, other periods are also envisaged depending on the desired colours to be viewed from the respective diffraction gratings 318.

With regard to the optical effect device 300b, it is also envisaged that the diffraction gratings 318 may be disposed on the first facets 310 and the second facets 312 instead of the third facets 314 and the fourth facets 316. It is also envisaged that diffraction gratings 318 may be disposed on all the first facets 310, second facets 312, third facets 314, and fourth facets 316, or disposed on one or more of the first facets 310, second facets 312, third facets 314, and fourth facets 316. For example, diffraction gratings 318 orientated in a first direction can be formed on all the first and second facets 310, 312 and diffraction gratings 318 orientated in a second and third direction can formed on all the third and fourth facets 314, 316, respectively. This would provide variance in the optical effect when orientated in directions not associated with the typical flip optical effect.

The addition of diffraction gratings 318 introduces colour into the first and second optical effects when viewed in at least partially collimated light, as the light is diffracted and therefore colour effects are viewable, and also widens the viewing angle range in which each of the image channels are visible due to the light scattering effect of the diffraction gratings 318. If the structures 308 are not overcoated with a reflective layer, when viewing the optical effect device 300b in reflected or transmitted white light that is at least partially collimated, or from a point source, the first and second optical effects are observed in multiple colours and, as the optical effect device 300b is rotated about the about the X axis, or offset from the light source, the optical effects viewed transition between the first and second optical effects.

Although the first facets 310 and the second facets 312 have been described and illustrated as not defining a slope with respect to the first surface 304 of the substrate 302, it is envisaged that the first facets 310 and the second facets 312 may define an angle with respect to the first surface 304 of the substrate 302 that is different to the angle β and the angle ω. In this case, the first facets 310 and the second facets 312 would face in different directions to each other and the first and second directions of the third facets 314 and the fourth facets 316, respectively.

It is also envisaged that the thickness of each structure 308 may be reduced using the approach described above with respect to the optical effect device 100d.

### Fourth Exemplary Embodiment of the Invention

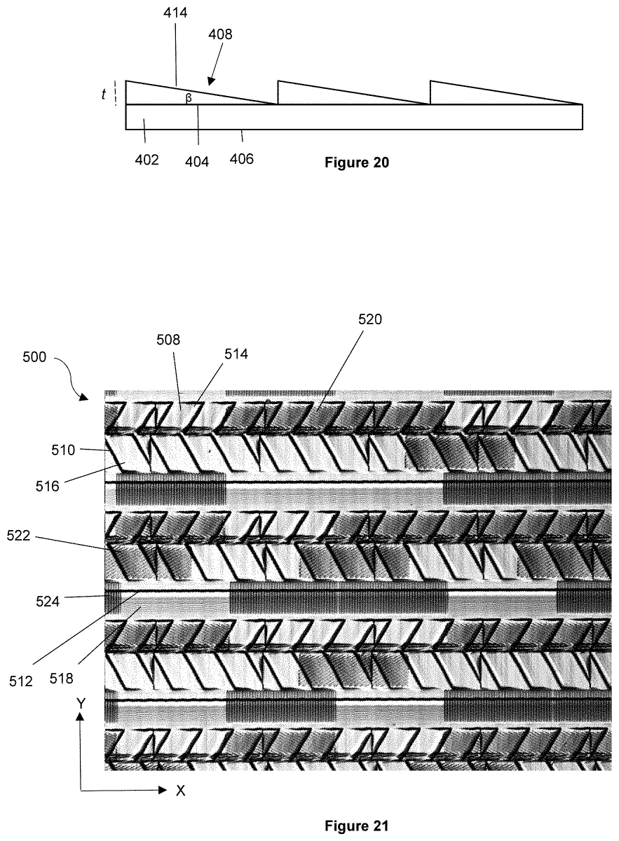

FIG. 19 shows an optical effect device 400 in the form of a security device according to a fourth embodiment of the present invention. The optical effect device 400 comprises a substrate 402 having a first surface 404 and a second surface 406 (see FIG. 20).

Arranged on the first surface 404 of the substrate 402 is a first plurality of structures 408 that define a first image channel having a first projection angle range, a second plurality of structures 410 that define a second image channel having a second projection angle range, and a third plurality of structures 412 that define a third image channel having a third projection angle range. Each structure 408 has a facet 414 that faces in a first direction, each structure 410 has a facet 416 that faces in a second direction that is different to the first direction, and each structure 412 has a facet 418 that faces in a third direction that is different to both the first and second directions.

Each facet 414, 416, 418 defines a slope with respect to the first surface 404 of the substrate 402. The facets 414 of the structures 408 define the same slope angle β with respect to the first surface 404 of the substrate 402 and the structures 408 have the same maximum thickness t (see FIG. 20 for example). Similarly, the facets 416, 418 of the respective structures 410, 412 define the same slope angle with respect to the first surface 404 of the substrate 402 and the structures 410, 412 have the same maximum thickness. It is envisaged that the maximum thickness of the structures 408, 410, 412 may or may not be uniform and/or that the slope angle defined by each of the facets 414, 416, 418 with respect to the first surface 404 of the substrate 402 may or may not be uniform.

As best seen in FIG. 19, the plurality of structures 408, 410, 412, each have a unique orientation in the XY plane. It will therefore be appreciated that the plurality of structures 408, 410, 412 each have a unique in-plane orientation with respect to the plane of the first surface 404 of the substrate 402. The structures 408 have an in-plane orientation of 90 degrees with respect to the plane of the first surface 404 of the substrate 402 such that the respective facets 414 face in a first direction. The structures 410 have an in-plane orientation of 210 degrees with respect to the plane of the first surface 404 of the substrate 402 such that the respective facets 416 face in a second direction. The structures 412 have an in-plane orientation of 330 degrees with respect to the plane of the first surface 404 of the substrate 402 such that the respective facets 418 face in a third direction. Each of the plurality of structures 408, 410, 412 therefore have an in-plane orientation with respect to the plane of the first surface 404 of the substrate 402 that is separated by 120 degrees. It is envisaged that the plurality of structures 408, 410, 412 may have other in-plane orientations and/or may have an in-plane separation angle other than 120°.

The facets 414 of the first plurality of structures 408 define a first optical effect when viewed from a first viewing angle range, the facets 416 of the second plurality of structures 410 define a second optical effect when viewed from a second viewing angle range that is different to the first viewing angle range, and the facets 418 of the third plurality of structures 412 define a third optical effect when viewed from a third viewing angle range that is different to both the first and second viewing angle ranges. The optical effects may be viewable from viewing positions located on the same side as the first surface 404 and the second surface 406 of the substrate 402 if the substrate 402 and the structures 408, 410, 412 are formed from a transparent material.

Each optical effect defined by the respective image channel is a dithered binary image derived by applying an amplitude modulation or frequency modulation dithering algorithm to an input greyscale image. An example of a dithering algorithm is a diffusion dithering algorithm. Each binary “on” pixel of the first optical effect is implemented in the optical effect device 400 as one or more structures 408. Similarly, each binary “on” pixel of the second and third image channels is implemented in the optical effect device 400 as one or more structures 410 and one or more structures 412, respectively. Accordingly, the structures 408, 410, 412 are only arranged at locations on the first surface 404 of the substrate 402 that correspond to the binary “on” pixels of the first, second, and third optical effects. Each pixel defined by one or more respective structures 408, 410, 412 may represent a foreground or background pixel. It will therefore be appreciated that portions of the first surface 404 of the substrate 402 will be absent of any structures 408, 410, 412 where the respective image requires a binary “off”. That is, in one embodiment, an input binary black and white image for the first optical effect is converted into the optical effect device 400 by arranging structures 408 where a black pixel is found in the input binary image of the first optical effect and, where a white pixel is found in the input binary image of the first optical effect, having an absence of a corresponding structure 408. It will be appreciated that this will be similar for the second and third optical effects.

The optical effect device 400 therefore interleaves three images that can be projected to an observer at three pre-defined viewing angle ranges. In addition, the choice of in-plane orientation allows for effects which are viewable when a rectangular document is rotated about either primary axes (both X and Y in FIG. 19) with respect to a light source, or when a rectangular document is rotated about the Z axis (in-plane rotation) with respect to a light source. It will therefore be appreciated that the optical effect device 400 provides a 3-flip optical effect.

The general structure of embodiments of the optical effect device 400 are outlined below:
The structures 408, 410, 412 may be formed from a transparent material, for example, a radiation curable resin (discussed in more detail below);
The substrate 402 may also be transparent and may be formed as a foil (such as for application to a security document) or a polymer substrate (e.g., a banknote polymer substrate);
The structures 408, 410, 412 may be overcoated with a clear protective layer that may have a different refractive index to that of the material used to form the structures 408, 410, 412. The clear protective layer may be sufficiently thick to prevent mechanical copying (i.e., contact copying) of the structures 308 (discussed in more detail below); and
Alternatively, the structures 408, 410, 412 may be overcoated with a reflective layer. The reflective layer may be sufficiently thick to prevent mechanical copying (i.e., contact copying) of the structures 408, 410, 412. Alternatively, the reflective layer may be thin and overcoated with a clear protective layer that is sufficiently thick to prevent mechanical copying (i.e., contact copying) of the structures 408, 410, 412.

If the structures 408, 410, 412 are not overcoated with a reflective layer or are overcoated with a semi-transparent reflective layer, the optical effects may be viewed in both transmission and reflectance. In this case, the optical effects may be viewable from respective viewing positions located on the same side as the first surface 404 and on the same side as the second surface 406 having respective viewing angle ranges. This will also be the case if the structures 408, 410, 412 are overcoated with a thin reflective layer (e.g., less than the maximum thickness of the structures 408, 410, 412, but sufficiently thick to substantially prevent transmission of light), however, in this case, the optical effects will only be viewable in reflected light.

If the structures 408, 410, 412 are overcoated with a thick reflective layer such that mechanical copying of the structures 408, 410, 412 may be prevented/restricted, the optical effects will only be viewable in reflectance from viewing positions located on the same side as the second surface 406 having respective viewing angle ranges.

It is also envisaged that the substrate 402 may be formed from an opaque material (e.g., a foil or a polymer of a banknote) and that the structures 408, 410, 412 may be formed from a transparent material (e.g., a radiation curable resin). In this case, it will be appreciated that the optical effects will only be viewable in reflectance from viewing positions located on the same side as the first surface 404 having respective viewing angle ranges. The visibility of the optical effects in this case may be improved by overcoating the structures 408, 410, 412 with a thin reflective layer.

Although the optical effects projected by the optical effect device 400 have been described as being binary images, it will be appreciated that the optical effects may be implemented by the respective image channels as:
monochromatic ‘silhouette’ binary images; or
binary dithered halftone images.

Diffraction gratings may be disposed on one or more of the facets 414, 416, 418. The lines of each diffraction grating may extend in a direction parallel to the slope of the respective facet 414, 416, 418. In other words, the lines of each diffraction grating extend in the direction of maximum slope of the respective facet 414, 416, 418. Alternatively, the lines of the diffraction gratings may be oriented in other directions depending on the desired colours to be projected in the viewing angle ranges of the respective first, second, and third image channels, for example, in a direction extending perpendicular or at an angle with respect to the direction of maximum slope of the respective facet 414, 416, 418. The diffraction gratings may have a period of 1.2 μm to 3.2 μm, however, other periods are also envisaged depending on the desired colours to be viewed from the respective diffraction gratings.

The addition of diffraction gratings introduces colour into the optical effects when viewed in at least partially collimated light and also widens the viewing angle range ranges in which each of the image channels are visible due to the light scattering effect of the diffraction gratings. In this embodiment, if the structures 408, 410, 412 are not overcoated with a reflective layer, when viewing the optical effect device 400 in reflected or transmitted white light that is at least partially collimated, or from a point source, the optical effects are observed in multiple colours and, as the optical effect device 400 is rotated about the about the X and/or Y and/or Z axes, or offset from the light source, the optical effects viewed transition between the optical effects.

It is also envisaged that the thickness of each structure 408 may be reduced using the approach described above with respect to the optical effect device 100d.

### Fifth Exemplary Embodiment of the Invention

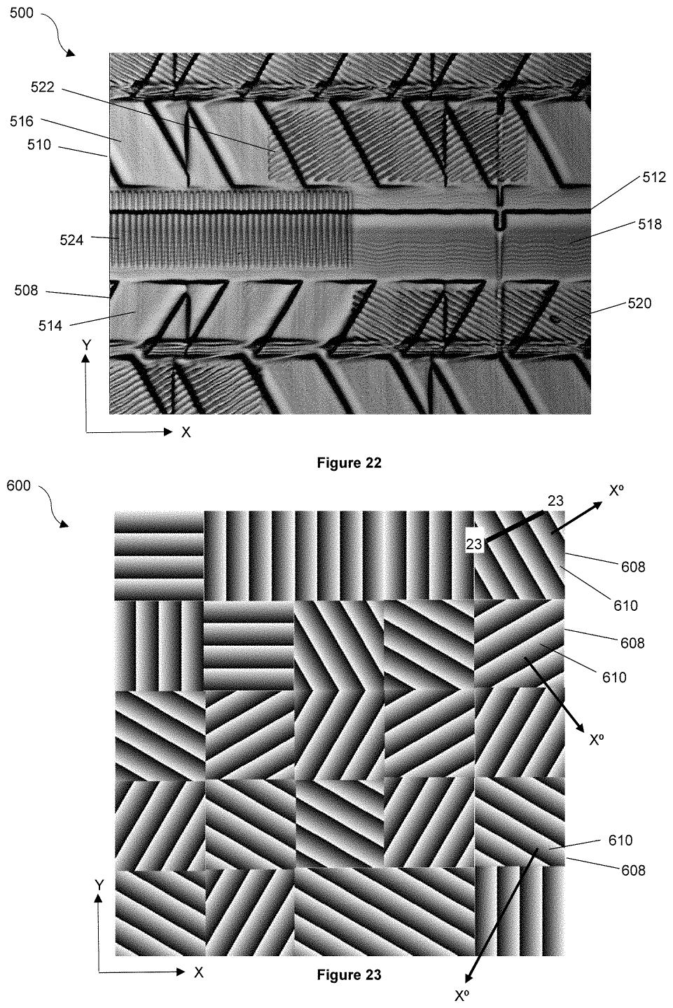

FIGS. 21 and 22 shows an optical effect device 500 in the form of a security device according to a fifth embodiment of the present invention. The optical effect device 500 is similar to the optical effect device 400, except that the structures 508, 510, 512 are arranged over the entire first surface 504 of the substrate 502 and that diffraction gratings 520, 522, 524 are disposed on one or more of the respective facets 514, 516, 518.

Features of the optical effect device 500 that are identical or equivalent to those of the optical effect device 400 are provided with reference numerals that are equivalent to those of the optical effect device 400 but incremented by 100. For features that are identical between the optical effect device 400 and the optical effect device 500, it will be appreciated that the above description of these features in relation to the optical effect device 400 is also applicable to the corresponding identical/equivalent features found in the optical effect device 500. Accordingly, the identical features between the optical effect device 400 and the optical effect device 500 will not again be described below in relation to the optical effect device 500, as these features of the optical effect device 500 have already been described above with respect to the optical effect device 400.

The first plurality of structures 508 define a first image channel having a first projection angle range, the second plurality of structures 510 define a second image channel having a second projection angle range, and the third plurality of structures 512 define a third image channel having a third projection angle range. The diffraction gratings 520 disposed on one or more of the facets 514 of the first plurality of structures 508 define a first optical effect when viewed from a first viewing angle range, the diffraction gratings 522 disposed on one or more of the facets 516 of the second plurality of structures 510 define a second optical effect when viewed from a second viewing angle range that is different from the first viewing angle range, and the diffraction gratings 524 disposed on one or more of the facets 518 of the third plurality of structures 512 define a third optical effect when viewed from a third viewing angle range that is different to the first and second viewing angle ranges. The optical effects of the optical effect device 500 may be viewable from viewing positions located on the same side as the first surface 504 and the second surface 506 of the substrate 502 if the substrate 502 and the structures 508, 510, 512 are formed from a transparent material.

The diffraction gratings 520, 522, 524 are disposed on one or more respective facets 514, 516, 518 according to a dither pattern derived from a dithering algorithm to input a greyscale image. The lines of each diffraction grating 520, 522, 524 extend in a direction parallel to the slope of the respective facet 514, 516, 518. In other words, the lines of each diffraction grating 520, 522, 524 extend in the direction of maximum slope of the respective facet 514, 516, 518. It is also envisaged however that the lines of each diffraction grating 520, 522, 524 could be oriented in other directions depending on the desired colour to be projected at the viewing angle ranges of the respective first, second, and third image channels, for example, in a direction extending perpendicular or at an angle with respect to the direction of maximum slope of the respective facet 514, 516, 518. Each diffraction grating 520, 522, 524 may have a period of 1.2 μm to 3.2 μm, however, other periods are also envisaged depending on the desired colours to be viewed from the respective diffraction gratings 520, 522, 524.

The optical effect device 500 therefore interleaves three images that can be projected to an observer at three pre-defined viewing angle ranges. In addition, the choice of in-plane orientation allows for effects which are viewable when a rectangular document is rotated about either primary axes (both X and Y in FIG. 21) with respect to a light source, or when a rectangular document is rotated about the Z axis (in-plane rotation) with respect to a light source. It will therefore be appreciated that the optical effect device 500 provides a 3-flip optical effect.

The general structure of embodiments of the optical effect device 500 are outlined below:
The structures 508, 510, 512 may be formed from a transparent material, for example, a radiation curable resin (discussed in more detail below);
The substrate 502 may also be transparent and may be formed as a foil (such as for application to a security document) or a polymer substrate (e.g., a banknote polymer substrate);
The structures 508, 510, 512 may be overcoated with a clear protective layer that may have a different refractive index to that of the material used to form the structures 508, 510, 512. The clear protective layer may be sufficiently thick to prevent mechanical copying (i.e., contact copying) of the structures 308 (discussed in more detail below); and
Alternatively, the structures 508, 510, 512 may be overcoated with a reflective layer. The reflective layer may be sufficiently thick to prevent mechanical copying (i.e., contact copying) of the structures 508, 510, 512. Alternatively, the reflective layer may be thin and overcoated with a clear protective layer that is sufficiently thick to prevent mechanical copying (i.e., contact copying) of the structures 508, 510, 512.

If the structures 508, 510, 512 are not overcoated with a reflective layer or are overcoated with a semi-transparent reflective layer, the optical effects may be viewed in both transmission and reflectance. In this case, the optical effects may be viewable from respective viewing positions located on the same side as the first surface 504 and on the same side as the second surface 506 having respective viewing angle ranges. This will also be the case if the structures 508, 510, 512 are overcoated with a thin reflective layer (e.g., less than the maximum thickness of the structures 508, 510, 512, but sufficiently thick to substantially prevent transmission of light), however, in this case, the optical effects will only be viewable in reflected light.

If the structures 508, 510, 512 are overcoated with a thick reflective layer such that mechanical copying of the structures 508, 510, 512 may be prevented/restricted, the optical effects will only be viewable in reflectance from viewing positions located on the same side as the second surface 506 having respective viewing angle ranges.

It is also envisaged that the substrate 502 may be formed from an opaque material (e.g., a foil or a polymer of a banknote) and that the structures 508, 510, 512 may be formed from a transparent material (e.g., a radiation curable resin). In this case, it will be appreciated that the optical effects will only be viewable in reflectance from viewing positions located on the same side as the first surface 404 of the substrate 502. The visibility of the optical effects in this case may be improved by overcoating the structures 508, 510, 512 with a thin reflective layer.

If the structures 508, 510, 512 are not overcoated with a reflective layer, when viewing the optical effect device 500 in reflected or transmitted diffuse white light, the optical effects of the optical effect device 500 are observed in black and white and, as the optical effect device 500 is rotated about the X and/or Y and/or Z axes, or offset from the light source, the optical effects viewed transition between the first, second, and third optical effects. When viewing the optical effect device 500 in reflected or transmitted white light that is at least partially collimated, or from a point source, the optical effects of the optical effect device 500 are observed in multiple colours and, as the optical effect device 500 is rotated about the X and/or Y and/or Z axes, or offset from the light source, the optical effects viewed transition between the first, second, and third optical effects.

Through the appropriate selection of grating frequency, depth, and orientation of the lines of the diffraction gratings 520, 522, 524, the optical effects projected by each of the respective image channels of the optical effect device 500 at a particular angle can be a true colour image. For example, the grating frequency, depth, and orientation of the lines of the diffraction gratings 520, 522, 524 can be selected such that they project a two-dimensional array of RGB coloured image pixels such that the respective image channels define a desired full colour image intended to be observed at a particular angle with a substantially collimated white light source. The images defined by the respective diffraction gratings 520, 522, 524 of each image channel could have multiple tones of one or more desired colours.

The diffraction gratings 520, 522, 524 can be disposed on one or more of the respective facets 514, 516, 518 such that the respective image channels define:
a monochromatic ‘silhouette’ binary image;
a binary dithered halftone image; or
a dithered binary image.

It is also envisaged that the thickness of each structure 508 may be reduced using the approach described above with respect to the optical effect device 100d.

### Sixth Exemplary Embodiment of the Invention

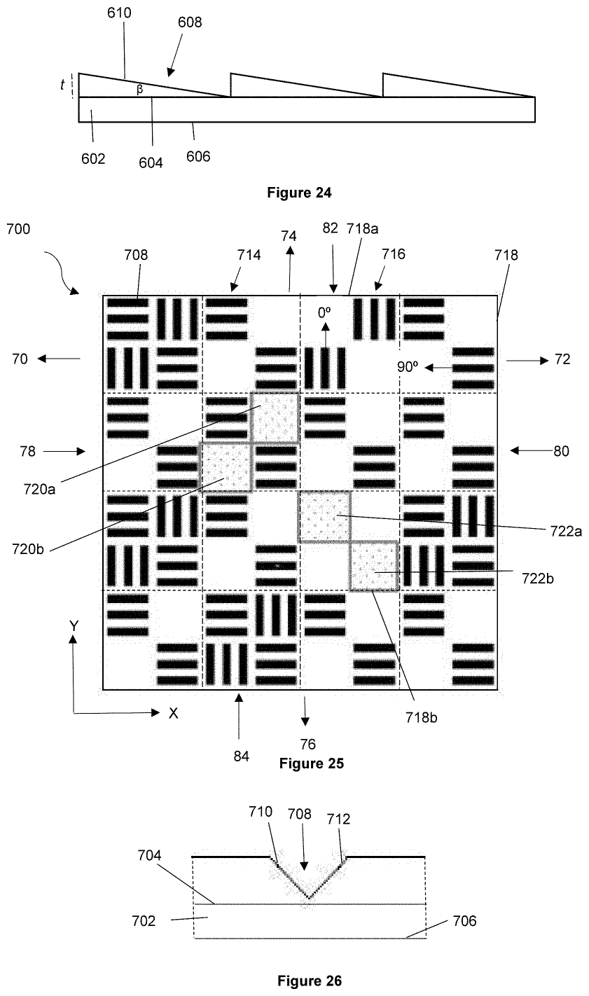

FIG. 23 shows an optical effect device 600 in the form of a security device according to a sixth embodiment of the present invention. The optical effect device 600 comprises a substrate 602 having a first surface 604 and a second surface 606 (see FIG. 24).

Arranged on the first surface 604 of the substrate 602 is a plurality of structures 608. Each structure 608 has a plurality of facets 610 that each define a slope having an angle β with respect to the first surface 604 of the substrate 602. Each structure 608 has an orientation in the XY plane. Accordingly, each structure 608 and its respective facets 610 have an in-plane orientation of X degrees with respect to the plane of the first surface 604 of the substrate 602.

The in-plane orientation and/or the slope angle β of the facets 610 of each structure 608 is modulated in accordance with an input array of scalar values. For example, for greyscale images with 256 levels of grey per pixel, the scalar values for greyscale may have a value in the range of 0 to 255, where zero is taken to be black and 255 is taken to be white.

In an embodiment of the optical effect device 600, the slope angle β of each facet 610 is the same but the in-plane orientation of each structure 608 with respect to the plane of the first surface 604 of the substrate 602 is modulated in accordance to an input scalar value, for example a greyscale scalar value of an input image. It will therefore be appreciated that each structure 608 and its respective facets 610 have a unique in-plane orientation between 0 degrees and say 180 degrees with respect to the plane of the first surface 604 of the substrate 602 based on the greyscale scalar value of the input image. For example, the facets 610 of a structure 608 at a particular location (X, Y) on the first surface 604 of the substrate 602 may have a constant slope angle β but have an in-plane orientation with respect to the first surface 604 of the substrate 602 equal to an input greyscale value (e.g., 0 to 255) divided by 255 and multiplied by 180 degrees.

In another embodiment of the optical effect device 600, each structure 608 may have the same in-plane orientation of X degrees with respect to the plane of the first surface 604 of the substrate 602 but the slope angle β of the facets 610 of each structure 608 may be modulated in accordance with an input scalar value, for example a greyscale scalar value of an input image. For example, the facets 610 of a structure 608 at a particular location (X, Y) on the first surface 604 of the substrate 602 may have a slope angle β equal to an input greyscale value (e.g., 0 to 255) divided by 255 and multiplied by 45 degrees.

In another embodiment of the optical effect device 600, it is envisaged that the in-plane orientation with respect to the plane of the first surface 604 of the substrate 602 and the slope angle β of the facets 610 of each structure 608 may be modulated in accordance with an input scalar value, for example a greyscale scalar value of an input image.

The facets 610 of the optical effect device 600 define a contrast switch optical effect when viewed in a range of viewing angle ranges. The contrast switch optical effect provided by the optical effect device 600 may be a dithered binary image derived by applying an amplitude modulation or frequency modulation dithering algorithm to input a greyscale image. An example of a dithering algorithm is a diffusion dithering algorithm.

Each pixel of the contrast switch optical effect is implemented in the optical effect device 600 as one structure 608. The structures 608 are only arranged at locations on the first surface 604 of the substrate 602 that correspond to the pixels of the input greyscale image. Each pixel defined by structure 608 may represent a foreground or background pixel. In some embodiments, it will therefore be appreciated that portions of the first surface 604 of the substrate 602 will be absent of any structures 608. In other embodiments, every input image pixel (whether it is considered to be a foreground pixel, a background pixel, or neither) is represented with a corresponding structure 608.

According to one embodiment, each of the foreground and background pixels of an image will be defined by a respective structure 608 that is modulated as described above. In this case, when the viewing angle of an observer viewing the optical effect device 600 is changed, the brightness of the foreground and background pixels will begin to reverse until the contrast of the foreground and background pixels has switched (i.e., the contrast of the optical effect is inverted).

For a greyscale image having many different grey levels (i.e., tones of grey), the image will generally not have any identifiable foreground or background pixels. Accordingly, all the pixels of a greyscale image will be defined by a respective structure 608 that is modulated as describe above. When the viewing angle of an observer viewing the optical effect device 600 is changed, the brightness of each pixel will begin to reverse until the contrast of each pixel has switched (i.e., the contrast of the optical effect is inverted).

According to another embodiment, only the foreground or the background pixels of an image will be defined by a respective structure 608 that is modulated as described above. In this case, a disappearing image effect will be provided instead of a contrast switch effect. When the viewing angle of an observer viewing the optical effect device 600 is changed, the brightness of each pixel will increase or decrease, thus giving the appearance of a disappearing image.

The optical effect device 600 can be projected to an observer at a two-dimensional array of viewing angle ranges, thereby providing sampling of the contrast switch optical effect along two axes.

The general structure of embodiments of the optical effect device 600 are outlined below:
The structures 608 may be formed from a transparent material, for example, a radiation curable resin (discussed in more detail below);
The substrate 602 may also be transparent and may be formed as a foil (such as for application to a security document) or a polymer substrate (e.g., a banknote polymer
The structures 608 may be overcoated with a clear protective layer that may have a different refractive index to that of the material used to form the structures 608. The clear protective layer may be sufficiently thick to prevent mechanical copying (i.e., contact copying) of the structures 608 (discussed in more detail below); and
Alternatively, the structures 608 may be overcoated with a reflective layer. The reflective layer may be sufficiently thick to prevent mechanical copying (i.e., contact copying) of the structures 608. Alternatively, the reflective layer may be thin and overcoated with a clear protective layer that is sufficiently thick to prevent mechanical copying (i.e., contact copying) of the structures 608.

If the structures 608 are not overcoated with a reflective layer or are overcoated with a semi-transparent reflective layer, the optical effects may be viewed in both transmission and reflectance. Accordingly, in this case, the optical effects may be viewable from viewing positions located on the same side as the first surface 604 and on the same side as the second surface 606 having respective viewing angle ranges. This will also be the case if the structures 608 are overcoated with a thin reflective layer (e.g., less than the maximum thickness of the structures 608, but sufficiently thick to substantially prevent transmission of light), however, in this case, the optical effects will only be viewable in reflected light.

If the structures 608 are overcoated with a thick reflective layer such that mechanical copying of the structures 608 may be prevented/restricted, the optical effects will only be viewable in reflectance from viewing positions located on the same side as the second surface 606 having respective viewing angle ranges.

It is also envisaged that the substrate 602 may be formed from an opaque material (e.g., a foil or a polymer of a banknote) and that the structures 608 may be formed from a transparent material (e.g., a radiation curable resin). In this case, it will be appreciated that the optical effects will only be viewable in reflectance from viewing positions located on the same side as the first surface 604 of the substrate 602. The visibility of the optical effects in this case may be improved by overcoating the structures 608 with a thin reflective layer.

Diffraction gratings may be disposed on one or more of the facets 610 of the optical effect device 600. The lines of each diffraction grating may extend in a direction parallel to the slope of the facet 610. In other words, the lines of each diffraction grating extend in the direction of maximum slope of the respective facet 610. Alternatively, the lines of the diffraction gratings may be oriented in other directions depending on the desired colours to be projected at the viewing angle ranges of the contrast switch optical effect, for example, in a direction extending perpendicular or at an angle with respect to the direction of maximum slope of the respective facet 610. The diffraction gratings may have a period of 1.2 μm to 3.2 μm, however, other periods are also envisaged depending on the desired colours to be viewed from the respective diffraction gratings.

The addition of diffraction gratings introduces colour into the contrast switch optical effect when viewed in at least partially collimated light and also widens the viewing angle ranges in which the contrast switch optical effect is visible due to the scattering effect of the diffraction gratings. In this embodiment, if the structures 608 are not overcoated with a reflective layer, when viewing the optical effect device 600 in reflected or transmitted white light that is at least partially collimated, or from a point source, the contrast switch optical effect is observed in multiple colours and, as the optical effect device 600 is rotated about the about the X and/or Y and/or Z axes, or offset from the light source, the colour contrast of the contrast switch optical effect varies.

It is also envisaged that the thickness of each structure 608 may be reduced using the approach described above with respect to the optical effect device 100d.

### Seventh Exemplary Embodiment of the Invention

FIG. 25 shows an optical effect device 700 in the form of a security device according to a seventh embodiment of the present invention. The optical effect device 700 comprises a substrate 702 having a first surface 704 and a second surface 706 (see FIG. 26).

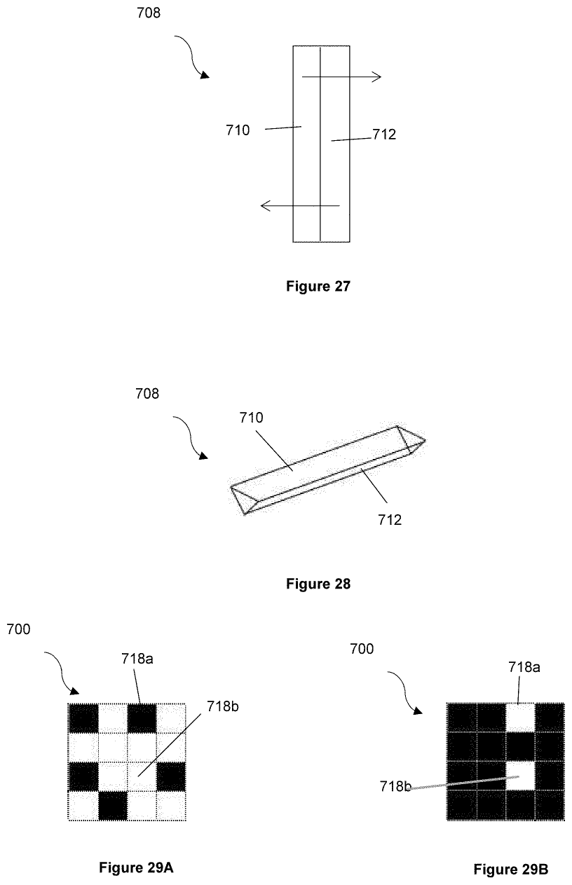

Arranged on the first surface 704 of the substrate 702 is a plurality of structures 708. Referring to FIGS. 26 to 28, each structure 708 is approximately in the form of a V-shaped groove and has a first facet 710 and a second facet 712. As best seen in FIG. 26, the first facet 710 and second facet 712 of each structure 708 face in different directions.

Referring to FIG. 25, the plurality of structures 708 are grouped into a first group of structures 714 that define a first image channel and a second group of structures 716 that define a second image channel. As best seen in FIG. 25, the first group of structures 714 extend in the X direction in FIG. 25 and the second group of structures 716 extend in the Y direction in FIG. 25.

The first group of structures 714 and the second group of structures 716 each have a unique in-plane orientation in the XY plane. It will therefore be appreciated that the first group of structures 714 and the second group of structures 716 each have a unique in-plane orientation with respect to the plane of the first surface 704 of the substrate 702.

Each structure 708 of the first group of structures 714 has an in-plane orientation of 90 degrees with respect to the plane of the first surface 704 such that, for each structure 708 of the first group of structures 714, the first facet 710 faces in a first direction generally indicated by the arrow 74 and the second facet 712 faces in a second direction generally indicated by the arrow 76. The first facets 710 and the second facets 712 of the first group of structures 714 define a first facet set and the second facet set, respectively.

Each structure 708 of the second group of structures 716 has an in-plane orientation of 0 degrees with respect to the plane of the first surface 704 such that, for each structure 708 of the second group of structures 716, the first facet 710 faces in a third direction generally indicated by the arrow 70 and the second facet 712 faces in a fourth direction generally indicated by the arrow 72. The first facets 710 and the second facets 712 of the second group of structures 716 define a third facet set and the fourth facet set, respectively. It will therefore be appreciated that the in-plane orientation of the first group of structures 714 is perpendicular to the in-plane orientation of the second group of structures 716.

Referring to FIG. 25, the optical effect device 700 is divided into a plurality of cells 718. Each cell 718 corresponds to one pixel of both a first optical effect and a second optical effect. Each cell 718 is divided into first areas 722a, 722b corresponding to a pixel of the first optical effect and second areas 720a, 720b corresponding to a pixel of the second optical effect. Three structures 708 of the first group of structures 714 are arranged in several of the first areas 722a, 722b of the cells 718 to define respective black (or white) pixels of the first optical effect. Similarly, three structures 708 of the second group of structures 716 are arranged in several of the second areas 720a, 720b of the cells 718 to define respective black (or white) pixels of the second optical effect. Although FIG. 25 shows three structures 708 in several of the respective first areas 722a, 722b and second areas 720a, 720b, it will be appreciated that more or less than three structures 708 may be arranged in several of the first areas 722a, 722b and the second areas 720a, 720b.

The first facet set defines the first optical effect when the optical effect device 700 is viewed from a first viewing angle range generally indicated by the arrow 82. The second facet set defines the first optical effect when the optical effect device 700 is viewed from a second viewing angle range generally indicated by the arrow 84. The third facet set defines the second optical effect when the optical effect device 700 is viewed from a third viewing angle range generally indicated by the arrow 78. The fourth facet set defined defines the second optical effect when the optical effect device 700 is viewed from a fourth viewing angle range generally indicated by the arrow 80. It will therefore be appreciated that the first image channel defined by the first group of structures 714 has two projection angles and that the first optical effect is viewable from two respective viewing angle ranges. It will also be appreciated that the second image channel defined by the second group of structures 716 has two projection angles and that the second optical effect is viewable from two respective viewing angle ranges. The optical effects may be viewable from viewing positions located on the same side as the first surface 704 and the second surface 706 of the substrate 702 if the substrate 702 and the structures 708 are formed from a transparent material.

For the optical effect device 700 shown in FIG. 25, when the optical effect device 700 is viewed from viewing directions generally indicated by the arrows 78 and 80, the optical effect shown in FIG. 29A will be projected to an observer. Similarly, when the optical effect device 700 is viewed from viewing directions generally indicated by the arrows 82 and 84, the optical effect shown in FIG. 29B will be projected to an observer.

Referring to FIGS. 25 and 29A-B, cell 718a has several structures 708 of the second group of structures 716 but no structures 708 of the first group of structures 714. Accordingly, when the optical effect device 700 is viewed from viewing angle ranges generally indicated by the arrows 78 and 80, cell 718a will project a black pixel in the first optical effect (see FIG. 29A) and, when the optical effect device 700 is viewed from viewing angle ranges generally indicated by the arrows 82 and 84, cell 718a will project a white pixel in the second optical effect (see FIG. 29B). It will be appreciated that any cell 718 having structures 708 from the first group of structures 714 will project a black pixel in the first optical effect when the optical effect device 700 is viewed from viewing angle ranges generally indicated by the arrows 82 and 84.

Cell 718b does not have any structures 708 of either of the first and second group of structures 714, 716. Accordingly, cell 718b will project a white pixel in both the first and second optical effects.

The optical effect device 700 therefore interleaves two images (i.e., the first and second optical effects) that can be projected to an observer by rotating the optical effect device 700 about an axis that is normal to the plane of the optical effect device 700. It will therefore be appreciated that the optical effect device 700 provides a two-flip optical effect.

The general structure of embodiments of the optical effect device 700 are outlined below:
The structures 708 may be formed from a transparent material, for example, a radiation curable resin (discussed in more detail below);
The substrate 702 may also be transparent and may be formed as a foil (such as for application to a security document) or a polymer substrate (e.g., a banknote polymer substrate);
The structures 708 may be overcoated with a clear protective layer that may have a different refractive index to that of the material used to form the structures 708. The clear protective layer may be sufficiently thick to prevent mechanical copying (i.e., contact copying) of the structures 708 (discussed in more detail below); and
Alternatively, the structures 708 may be overcoated with a reflective layer. The reflective layer may be sufficiently thick to prevent mechanical copying (i.e., contact copying) of the structures 708. Alternatively, the reflective layer may be thin and overcoated with a clear protective layer that is sufficiently thick to prevent mechanical copying (i.e., contact copying) of the structures 708.

If the structures 708 are not overcoated with a reflective layer or are overcoated with a semi-transparent reflective layer, the optical effects may be viewed in both transmission and reflectance. In this case, the optical effects may be viewable from viewing positions located on the same side as the first surface 704 and on the same side as the second surface 706 having respective viewing angle ranges. This will also be the case if the structures 708 are overcoated with a thin reflective layer (e.g., less than the maximum thickness of the structures 708, but sufficiently thick to substantially prevent transmission of light), however, in this case, the optical effects will only be viewable in reflected light.

If the structures 708 are overcoated with a thick reflective layer so that mechanical copying of the structures 708 may be prevented/restricted, the optical effects will only be viewable in reflectance from viewing positions located on the same side as the second surface 706 of the substrate 702 having respective viewing angle ranges.

It is also envisaged that the substrate 702 may be formed from an opaque material (e.g., a foil or a polymer of a banknote) and that the structures 708 may be formed from a transparent material (e.g., a radiation curable resin). In this case, it will be appreciated that the optical effects will only be viewable in reflectance from viewing positions located on the same side as the first surface 704 of the substrate 702. The visibility of the optical effects in this case may be improved by overcoating the structures 708 with a thin reflective layer.

The optical effects projected by the optical effect device 700 may be implemented by the structures 708 as:
monochromatic ‘silhouette’ binary images;
binary dithered halftone images; or
binary dithered image.

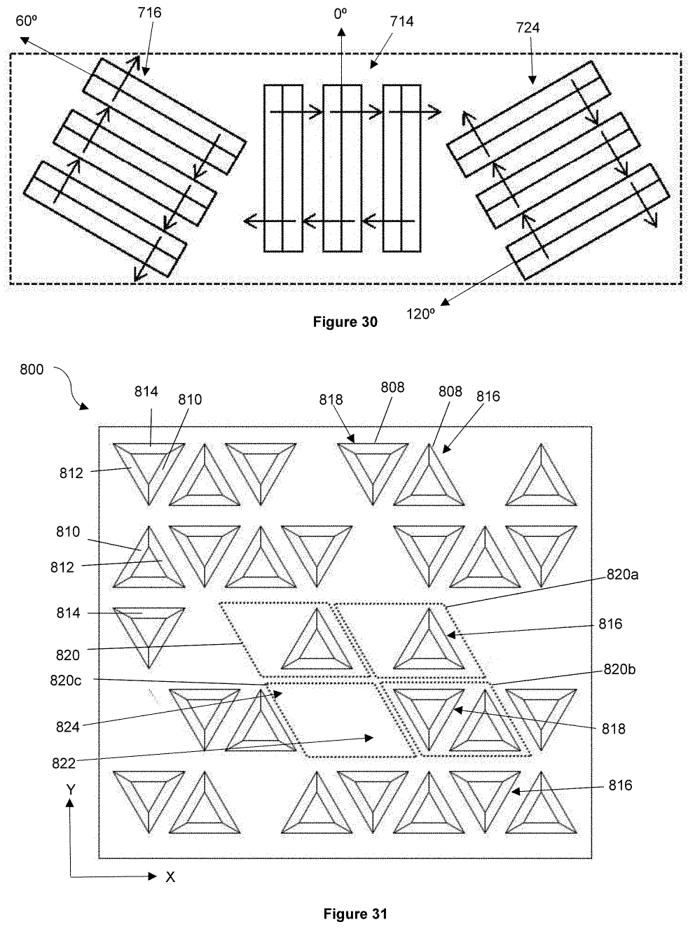

It will be appreciated that more than two images may be interleaved in the optical effect device 700 by arranging more groups of structures on the first surface 704 of the substrate 702. For example, referring to FIG. 30, the optical effect device 700 may have a third group of structures 724 that defines a third image channel. Similar to the first and second groups of structures 714, 716, the first facets 710 of the structures 708 of the third group of structures 724 define a third optical effect when the optical effect device 700 is viewed from a fifth viewing angle range and the second facets 712 of the structures 708 of the third group of structures 724 define the third optical effect when the optical effect device is viewed from a sixth viewing angle range. It will therefore be appreciated that the third image channel defined by the third group of structures 724 has two projection angle ranges and that the third optical effect is viewable from two respective viewing angle ranges.

In the example shown in FIG. 30, the first group of structures 714 has an in-plane orientation of 0 degrees with respect to the plane of the first surface 704, the second group of structures 716 has an in-plane orientation of 60 degrees with respect to the plane of the first surface 704, and the third group of structures 724 has an in-plane orientation of 120 degrees with respect to the plane of the first surface 704. It will therefore be appreciated that each group of structures 714, 716, 724 has an in-plane separation angle of 60 degrees.

The in-plane separation angle between each group of structures 714, 716, 724 is calculated by dividing 180 degrees by the number of group of structures. For example, if the optical effect device 700 interleaved four images, there would be four group of structures and the in-plane separation angle between adjacent groups of structures would be 45 degrees.

### Eighth Exemplary Embodiment of the Invention

FIG. 31 shows an optical effect device 800 in the form of a security document according to an eighth embodiment of the present invention. The optical effect device 800 is similar to the optical effect device 700, expect for the shape and configuration of the structures 808 of the optical effect device 800.

Features of the optical effect device 800 that are identical or equivalent to those of the optical effect device 700 are provided with reference numerals that are equivalent to those of the optical effect device 700 but incremented by 100. For features that are identical between the optical effect device 700 and the optical effect device 800, it will be appreciated that the above description of these features in relation to the optical effect device 700 is also applicable to the corresponding identical/equivalent features found in the optical effect device 800. Accordingly, the identical features between the optical effect device 700 and the optical effect device 800 will not again be described below in relation to the optical effect device 800, as these features of the optical effect device 800 have already been described above with respect to the optical effect device 700.

Arranged on the first surface 804 of the substrate 802 is a plurality of structures 808. Each structure 808 has the approximate geometry of a truncated triangular pyramid and has a first facet 810, a second facet 812, and a third facet 814. The first facet 810, the second facet 812, and the third facet 814 of each structure 808 face in a different direction.

The plurality of structures 808 are grouped into a first group of structures 816 that define a first image channel and a second group of structures 818 that define a second image channel. As best seen in FIG. 31, the first group of structures 816 point upwards in the Y direction of FIG. 31 and the second group of structures 818 point downwards in the Y direction of FIG. 31. The angle between the in-plane orientation of the first group of structures 816 and the second group of structure 818 is 180 degrees, however, other angles are also envisaged.

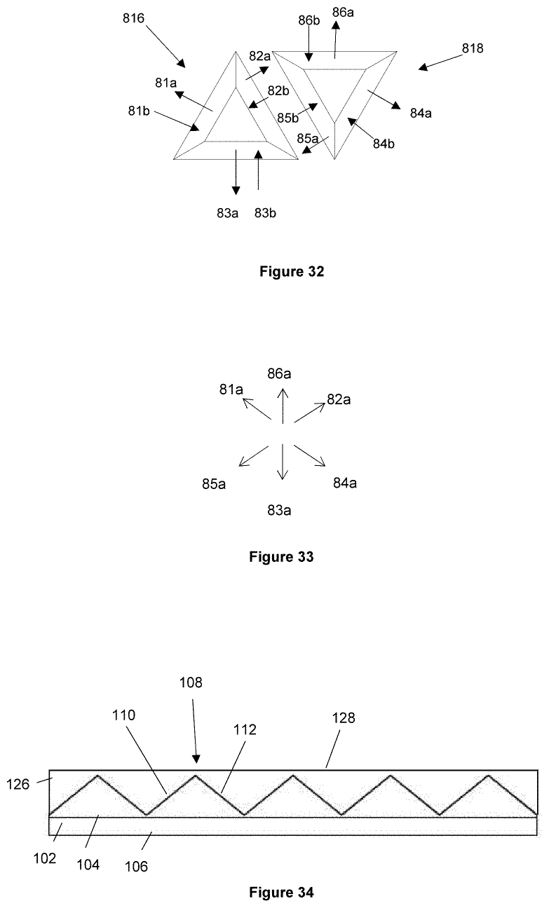

Referring to FIG. 32, for each structure 808 of the first group of structures 816, the first facet 810 faces in a first direction generally indicated by the arrow 81a, the second facet 812 faces in a second direction generally indicated by the arrow 82a, and the third facet 814 faces in a third direction generally indicated by the arrow 83a. The first facets 810, the second facets 812, and the third facets 814 of the first group of structures 816 define a first facet set, a second facet set and a third facet set, respectively.

For each structure 808 of the second group of structures 818, the first facet 810 faces in a fourth direction generally indicated by the arrow 84a, the second facet 812 faces in a fifth direction generally indicated by the arrow 85a, and the third facet 814 faces in a sixth direction generally indicated by the arrow 86a. The first facets 810, the second facets 812, and the third facets 814 of the second group of structures 818 define a fourth facet set, a fifth facet set, and a sixth facet set, respectively. As best seen in FIG. 33, the first and fourth facet sets face in opposite directions, the second and fifth facet sets face in opposite directions, and the third and sixth facet sets face in opposite directions.

Referring to FIG. 31, the optical effect device 800 is divided into a plurality of cells 820. Each cell 820 corresponds to one pixel of both the first optical effect and the second optical effect. Each cell 820 is divided into a first area 822 that corresponds to a pixel of the first optical effect and a second area 824 that corresponds to a pixel of the second optical effect.

The first facet set defines the first optical effect when the optical effect device 800 is viewed from a first viewing angle range generally indicated by the arrow 81b. The second facet set defines the first optical effect when the optical effect device 800 is viewed from a second viewing angle range generally indicated by the arrow 82b. The third facet set defines the first optical effect when the optical effect device 800 is viewed from a third viewing angle range generally indicated by the arrow 83b. The fourth facet set defines the second optical effect when the optical effect device 800 is viewed from a fourth viewing angle range generally indicated by the arrow 84b. The fifth facet set defines the second optical effect when the optical effect device 800 is viewed from a fifth viewing angle range generally indicated by the arrow 85b. The sixth facet set defines the second optical effect when the optical effect device 800 is viewed from a sixth viewing angle range generally indicated by the arrow 86b. It will therefore be appreciated that the first image channel defined by the first group of structures 816 has three projection angle ranges and that the first optical effect is viewable from three respective viewing angle ranges. It will also be appreciated that the second image channel defined by the second group of structures 818 has three projection angle ranges and that the second optical effect is viewable from three respective viewing angle ranges. The optical effects may be viewable from viewing positions located on the same side as the first surface 804 and the second surface 806 of the substrate 802 if the substrate 802 and the structures 808 are formed from a transparent material.

Referring to FIG. 31, cell 820a has a structure 808 from the first group of structures 816 but no structures 808 from the second group of structure 818. Accordingly, when the optical effect device 800 is viewed from any of the first to third viewing angle ranges 81b-83b, cell 820a will project a black pixel in the first optical effect and, when the optical effect device 800 is not viewed from any of the first to third viewing angle ranges 81b-83b, cell 820a projects a white pixel in the second optical effect. It will be appreciated that any cell 820 having a structure 808 from the second group of structures 818 will project a black pixel in the second optical effect when the optical effect device 800 is viewed from any one of the fourth to sixth viewing angle ranges 84b-86b.

Cell 820b has a structure 808 from both the first and second group of structures 816, 818. Accordingly, when the optical effect device 800 is viewed from any one of the first to third viewing angle ranges 81b-83b, cell 820b projects a black pixel in the first optical effect and, when the optical effect device 800 is viewed from any one of the fourth to sixth viewing angle ranges 84b-86b, cell 820b projects a black pixel in the second optical effect.

Cell 820c does not have any structures 808 of either of the first and second groups of structures 816, 818. Accordingly, cell 820c will project a white pixel in both the first and second optical effects.

The optical effect device 800 therefore interleaves two images (i.e. the first and second optical effects) that can be projected to an observer by rotating the optical effect device 800 about an axis that is normal to the plane of the optical effect device 800 and/or by tilting the optical effect device 800. It will therefore be appreciated that the optical effect device 800 provides a two-flip optical effect.

The two-flip optical effect provided by tilting the optical effect device 800 is possible because for each viewing angle range 81b-83b of the first optical effect, there is an opposite viewing angle range 84b-86b of the second optical effect, respectively. Referring to FIG. 32, the first viewing angle range 81b of the first optical effect is opposite to the fourth viewing angle range 84b of the second optical effect, the second viewing angle range 82b of the first optical effect is opposite to the fifth viewing angle range 85b of the second optical effect, and the third viewing angle range 83b of the first optical effect is opposite to the sixth viewing angle range 86b of the second optical effect. For example, the first optical effect is projected to an observer who is viewing the optical effect device 800 from the first viewing angle range 81b and, when the observer tilts the optical effect device 800 about an axis parallel to the in-plane orientation of the first facet set, the optical effect projected to the observer transitions from the first optical effect to the second optical effect.

The general structure of embodiments of the optical effect device 800 are outlined below:
The structures 808 may be formed from a transparent material, for example, a radiation curable resin (discussed in more detail below);
The substrate 802 may also be transparent and may be formed as a foil (such as for application to a security document) or a polymer substrate (e.g., a banknote polymer
The structures 808 may be overcoated with a clear protective layer that may have a different refractive index to that of the material used to form the structures 808. The clear protective layer may be sufficiently thick to prevent mechanical copying (i.e., contact copying) of the structures 808 (discussed in more detail below); and
Alternatively, the structures 808 may be overcoated with a reflective layer. The reflective layer may be sufficiently thick to prevent mechanical copying (i.e., contact copying) of the structures 808. Alternatively, the reflective layer may be thin and overcoated with a clear protective layer that is sufficiently thick to prevent mechanical copying (i.e., contact copying) of the structures 808.

If the structures 808 are not overcoated with a reflective layer or are overcoated with a semi-transparent reflective layer, the optical effects may be viewed in both transmission and reflectance. In this case, the optical effects may be viewable from viewing positions located on the same side as the first surface 804 and on the same side as the second surface 806 having respective viewing angle ranges. This will also be the case if the structures 808 are overcoated with a thin reflective layer (e.g., less than the maximum thickness of the structures 808, but sufficiently thick to substantially prevent transmission of light), however, in this case, the optical effects will only be viewable in reflected light.

If the structures 808 are overcoated with a thick reflective layer so that mechanical copying of the structures 808 may be prevented/restricted, the optical effects will only be viewable in reflectance from viewing positions located on the same side as the second surface 806 of the substrate 802 having respective viewing angle ranges.

The optical effect projected by the optical effect device 800 may be implanted by the structures 808 as:
monochromatic ‘silhouette’ binary images;
binary dithered halftone images; or
binary dithered images.

It is also envisaged that the substrate 802 may be formed from an opaque material (e.g., a foil or a polymer of a banknote) and that the structures 808 may be formed from a transparent material (e.g., a radiation curable resin). In this case, it will be appreciated that the optical effects will only be viewable in reflectance from viewing positions located on the same side as the first surface 804 of the substrate 802. The visibility of the optical effects in this case may be improved by overcoating the structures 808 with a thin reflective layer.

It will be appreciated that more than two images may be interleaved in the optical effect device 800. Similar to the optical effect device 700 illustrated in FIG. 30, the optical effect device 800 may interleave more than two images by having more than two groups of structures, where each group of structures defines an image channel that projects an optical effect. Each group of structures will have a unique in-plane orientation with respect to the first surface 804 of the substrate 802.

### Reflection and Transmission

When viewing the optical effects of each optical effect device 100-800 in reflection, the viewing angle range of each image channel will be defined by the angle of specular reflection from the respective facet set, which depends on the position and orientation of the respective facet set relative to the light source.

When viewing the optical effects of each optical effect device 100-800 in transmission, the viewing angle range of each image channel will be defined by the angle of refraction from the respective facet set, which depends on the position and orientation of the facet set relative to the light source.

### Protective Layer and Reflective Layer

According to an embodiment of each optical effect device 100-800, to improve the visibility of the optical effects, a reflective layer may be disposed on the plurality of structures. The reflective layer is preferably thin such that the optical effects can be viewed from viewing positions located on the same side as the first surface 104-804 and the second surface 106-806 of the substrate 102-802. The reflective layer may be formed from a metallic ink. However, other suitable materials known in the art may be used to form the reflective layer.

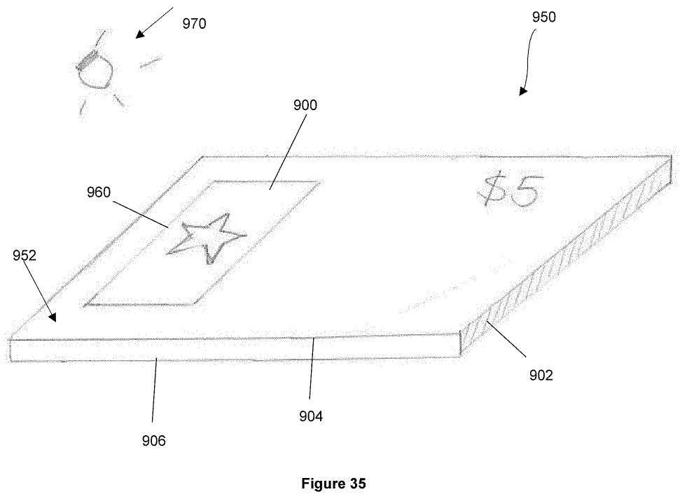

The reflective layer may be overcoated with a clear protective layer. Preferably, the clear protective layer is sufficiently thick such that the clear protective layer forms a first planar side of the optical effect device 100-800. As an example, FIG. 34 shows the optical effect device 100 having a clear protective layer 126 disposed over the reflective layer (not shown) and the plurality of structures 108 that forms a first planar side 128 of the optical effect device 100. It will be appreciated that each of the optical effect devices 100-800 may have a clear protective layer disposed over their respective structures in a similar manner to that shown in FIG. 34.

The planar side of the optical effect device 100-800 defined by the clear protective layer is advantageous because the clear protective layer can prevent mechanical copying of the plurality of structures, which could be used to produce counterfeits of the optical effect devices.

The planar side of the optical effect device 100-800 defined by the clear protective layer is also advantageous as the protective layer prevents contaminants such as liquids and/or particulates contacting the plurality of structures, which would interfere with the plurality of structures and reduce the visibility of the optical effects. This is particularly advantageous for optical effect devices 100-800 having structures that have shallow depths, which are only a few microns deep.

### Protective Layer

According to another embodiment of the optical effect devices 100-800, a thick clear protective layer may be disposed on the plurality of structures 108-808 such that the clear protective layer forms a first planar side of the optical device (for example see FIG. 34). The clear protective layer may be formed from a high refractive index layer, however, other suitable materials known in the art may be used to form the high refractive index layer.

The advantages discussed above with respect to the protective layer and reflective layer embodiment are also applicable to this embodiment.

### Reflective Layer

According to another embodiment of the optical effect devices 100-800, a thick reflective layer may be disposed on the structures such that the reflective layer forms a first planar side of the optical effect device 100-800 (for example, see FIG. 34, where for this embodiment the reference 126 refers to the thick reflective layer). It will be appreciated that the optical effects in this embodiment will only be viewable from viewing positions located on the same side as the second surface 106-806 of the substrate 102-802. The reflective layer may be formed from a metallic ink, however, other suitable materials known in the art may be used to form the reflective layer.

The planar side of the optical device defined by the reflective layer is advantageous because the reflective layer can prevent mechanical copying of the plurality of structures, which could be used to produce counterfeits of the optical effect device.

### Surface Structures

Although the above optical effect devices 100-800 have been described as having diffraction gratings disposed on one or more of the facets, it is also envisaged that other surface structures/textures may be applied to the facets of each of the above optical effect devices 100-800. Examples of other surface structures/textures that may be disposed on the facets of each of the above described optical effect devices 100-800 include surface roughness, micro-surface roughness, light scattering surfaces, micro-texture, micro-text, or combinations thereof.

### Security Document

FIG. 32 shows an embodiment of a security document 950 having a security device 900.

The security document 950 has a substrate 902, which is the main carrier of various security and design features of the security document 950. For ease of illustration, only one security device 900 is shown but it is well recognized that security documents typically have multiple security devices. The substrate 902, which is typically made from a transparent polymeric material, includes a first surface 904 and an opposing second surface 906, and are both substantially planar. One or more opacifying layers 952 may be provided in the selected regions of the security document 950, particularly when the substrate 902 is substantially transparent, so that design patterns, solid colours, text, or similar thereof can be directly formed on the opacifying layer 952 in a selected region of the substrate 902. The security device 900 according to an embodiment of the invention is located within the window region 960 of the security document 950, but this is not essential. As the security device 900 is integrally formed as part of the security document 950, the substrate 902 also acts as the substrate of the security device 900.

According to an embodiment of the security document 950, the security device 900 may be any one of the optical effect devices 100-800. It will therefore be appreciated that if any of the optical effect devices 100-800 are integrally formed with the security document 950, the substrate 902 of the security document 950 will form the respective substrate 102-802 of the optical effect device 100-800. The substrate 902 of the security device 950 forming the substrate 102-802 of the optical effect device 100-800 may be a polymer substrate (being the substrate of the relevant article or document) or a foil (typically understood to be an element which is applied, such as by hot stamping, to a relevant article or document).

According to another embodiment of the security document 950, the security device 900 may be any one of the optical effect devices 100-800, which is formed, for example, as a transfer film for applying to the substrate 902 of the security document 950. The substrate 102-802 of the optical effect device 100-800 applied to the security document 950 may be a polymer substrate or a foil.

### Manufacturing

By way of example, the optical effect devices 100-800 can be manufactured as follows.

A focused laser beam is raster scanned on a photoresist surface. The power of the laser beam is varied to form the structures of the optical effect device 100-800 in the photoresist. The power of the laser beam is also varied during the scan according to the desired maximum thickness of the structures. After the scan, the photoresist is developed/washed out to produce the structures. Subsequently, if required, the focused laser beam is raster scanned onto the photoresist to form the diffraction gratings on one or more of the structures. After the second scan, the photoresist is used to form a negative (or a positive) of the photoresist on a shim, which is subsequently attached to an embossing roller. Although two passes of the laser beam have been described to form the structures and any diffraction gratings disposed on the structures, it is also envisaged that only a single pass of the laser beam may be required to form both the structures and any diffraction gratings disposed on the structures.

After the shim is attached to an embossing roller, a radiation curable resin, preferably UV curable resin, is applied to the first surface 104-804 of the substrate 102-802 by a suitable printing process. While the radiation curable resin is still soft, the shim attached to an embossing roller, is embossed into the radiation curable ink to form the structures and any diffraction gratings on the structures. The radiation curable resin may be cured while the structures and any diffraction gratings on the structures 108-808 are embossed or afterwards.

According to another method, the laser methods described above may be used to form a negative of the structures of the optical effect device 100-800 into the photoresist. The photoresist is used to form a negative (or a positive) of the photoresist on a shim attached to an embossing roller, that is used to emboss the structures and any diffraction gratings on the structures into a radiation curable resin applied to the first surface 104-804 of the substrate 102-802. The radiation curable resin may be cured while the structures and any diffraction gratings on the structures 108-808 are embossed or afterwards.

According to another method where diffraction gratings are not required, a positive or negative of the structures of the optical effect device s 100-800 may be laser engraved directly into the embossing roller using a pulsed laser engraving system, for example a picosecond pulsed laser engraver.

By way of example, the optical effect devices 700-800 can be manufactured as follows.

A positive (or negative) of the structures 708, 808 of the optical effect device 700, 800 can be etched directly into an embossing roller. After the positive (or negative) of the structures 708, 808 has been etched into the embossing roller, a radiation curable resin, preferably UV curable resin, is applied to the first surface 704, 804 of the substrate 702, 802 by a suitable printing process. While the radiation curable resin is still soft, the embossing roller is embossed into the radiation curable ink to form the negative (or positive) of the structures 708, 808 of the optical effect device 700, 800. The radiation curable resin may be cured while the structures 708, 808 are embossed or afterwards.

Etching a positive or negative of the structures 708, 808 of the optical effect device 700, 800 directly into the embossing roller provides a number of benefits over the manufacturing method described above with respect to the optical devices 100-600 utilizing photoresist. These benefits include:
Lower cost—This is because expensive shims are not required to be formed and then applied to the embossing roller.
Shorter lead times—This is because the lead times associated with forming the shims is very long, since individual shim masters must first be made, followed by recombination of the masters into a full-size shim, which is then applied to an embossing roller. In this embodiment, the lead times can be reduced, as standard gravure cylinder manufacturing methods may be used to form the positive or negative of the structure 708, 808 directly into the embossing roller.
Embossing tooling is more robust/mechanically durable. As the shims are not required to be applied to the embossing roller, the embossing tooling of this method is more robust and durable. Further, the embossing tooling can be cleaned more often without sustaining damage compared to shims.
No witness marks. The step of recombining the master shims to make the full-size shim typically introduces Witness marks' in the full-size production shim. These marks appear as lines forming a rectangular perimeter around the structure in the shim that is to be embossed. These marks can cause a build-up of UV resin on the shim during production, making it necessary to frequently stop the production process in order to clean the shim. On the other hand, etching the positive or negative of the structures 708, 808 directly into the embossing roller makes the production process more efficient, since less downtime is required for cleaning the tooling, and the manufacturing process of the roller does not produce witness marks.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

Although the invention has been described with reference to a preferred embodiment, it will be appreciated by persons skilled in the art that the invention may be embodied in many other forms. It will be appreciated by persons skilled in the art that numerous variations and/or modifications may be made to the technology as shown in the specific embodiments without departing from the spirit or scope of technology as broadly described. The present embodiments are, therefore, to be considered in all respects as illustrative and not restrictive.

1. An optical effect device comprising:
a substrate having a first surface and a second surface;
a plurality of structures arranged on the first surface, each structure having a first facet and a second facet, the first facet of each structure being substantially parallel to the first surface of the substrate, the second facet of each structure defining a slope with respect to the first surface, and the first facets of the plurality of structures forming a first facet set,
wherein the first facet is disposed at the bottom of each structure, and the first facet set defines a first optical effect when the optical effect device is viewed from a first viewing angle range.

2. The optical effect device of claim 1, wherein each structure has a third facet and a fourth facet, the third facet of each structure is substantially parallel to the first surface of the substrate, the fourth facet of each structure faces in second direction and defines a slope with respect to the first surface of the substrate, the third facets of the plurality of structures forming a second facet set that defines a second optical effect when the optical effect device is viewed from a second viewing angle range and/or further comprising a surface structure disposed on one or more of the second facets and the fourth facets of the plurality of structures and/or a surface structure disposed on one or more of the first facets and the third facets of the plurality of structures.

3. An optical effect device comprising:
a substrate having a first surface and a second surface;
a first plurality of structures arranged on the first surface of the substrate, the first plurality of structures having a first in-plane orientation with respect to the first surface of the substrate, each structure of the first plurality of structures having a facet that faces in a first direction, the facets of the first plurality of structures forming a first facet set; and
a second plurality of structures arranged on the first surface of the substrate, the second plurality of structures having a second in-plane orientation with respect to the first surface of the substrate, each structure of the second plurality of structures having a facet that faces in a second direction, the facets of the second plurality of structures forming a second facet set,
wherein the first facet set defines a first optical effect when the optical effect device is viewed from a first viewing angle range and the second facet set defines a second optical effect when the optical effect device is viewed from a second viewing angle range,
wherein the optical effect device comprises diffractive structures disposed on the first facet set and on the second facet set.

4. The optical effect device of claim 3, further comprising a third plurality of structures arranged on the first surface of the substrate, the third plurality of structures having a third in-plane orientation with respect to the first surface of the substrate, each structure of the third plurality of structures having a facet that faces in a third direction, the facets of the third plurality of structures forming a third facet set that defines a third optical effect when the optical effect device is viewed from a third viewing angle range and/or each facet of each the first plurality of facets, the second plurality of facets, and the third plurality of facets defines a slope with respect to the first surface of the substrate.

5. The optical effect device of claim 4, wherein:
the structures of the first plurality of structures are arranged at locations on the first surface of the substrate corresponding to pixels of the first optical effect;
the structures of the second plurality of structures are arranged at locations on the first surface of the substrate corresponding to pixels of the second optical effect; and
the structures of the third plurality of structures are arranged at locations on the first surface of the substrate corresponding to pixels of the third optical effect.

6. An optical effect device comprising:
a substrate having a first surface and a second surface;
a plurality of structures arranged on the first surface, each structure having a first facet, the first facets of the plurality of structures forming a first facet set, and the first facet set defining a first optical effect when the optical effect device is viewed from a first viewing angle range,
wherein each structure corresponds to a pixel of the first optical effect, each pixel of the first optical effect having a scalar value corresponding to a shade of the pixel in the first optical effect, and each structure is modulated according to the scalar value of the respective pixel.

7. The optical effect device of claim 6, wherein the first facet of each structure defines a slope having an angle with respect to the first surface of the substrate and, for each structure, the angle of the slope of the first facet is modulated according to the scalar value of the respective pixel and/or each structure has an in-plane orientation with respect to the first surface of the substrate and the in-plane orientation of each structure is modulated according to the scalar value of the respective pixel and/or comprising a surface structure disposed on one or more of the first facets of the plurality of structures.

8. An optical effect device comprising:
a substrate having a first surface and a second surface;
a first plurality of structures arranged on the first surface, each structure of the first plurality of structures having a first facet that faces in a first direction and a second facet that faces in a second direction, the first facets of the first plurality of structures forming a first facet set, and the second facets of the first plurality of structures forming a second facet set,
wherein the first facet set defines a first optical effect when the optical effect device is viewed from a first viewing angle range and the second facet set defines the first optical effect when the optical effect device is viewed from a second viewing angle range,
wherein the optical effect device comprises diffractive structures disposed on the first facet set and on the second facet set.

9. The optical effect device of claim 8, wherein:
each structure of the first plurality of structures has a third facet;
for each structure of the first plurality of structures, the third facet faces in a third direction;
the third facets of the first plurality of structures form a third facet set; and
the third facet set defines the first optical effect when the optical effect device is viewed from a third viewing angle range.

10. The optical effect device of claim 8, wherein:
the structures of the first plurality of structures are arranged at locations on the first surface of the substrate corresponding to pixels of the first optical effect; and
the structures of the second plurality of structures are arranged at locations on the first surface of the substrate corresponding to pixels of the second optical effect.

11. The optical effect device of claim 1, wherein each optical effect is viewable in reflectance and transmission.

12. The optical effect device of claim 1, further comprising a reflective layer disposed on the plurality of structures.

13. The optical effect device of claim 1, further comprising a protective layer disposed over the plurality of structures.

14. A security document comprising a security element in the form of an optical effect device according to claim 1.

15. The security document of claim 14, wherein the security device is disposed in a half window or full window of the security document.
